(19) United States
(12) Patent Application Publication
(10) Pub. No.: US 2025/0344400 A1
(43) Pub. Date: Nov. 6, 2025

(54) ANTI-FERROELECTRIC TUNNEL JUNCTION WITH ASYMMETRICAL METAL ELECTRODES

(71) Applicant: Taiwan Semiconductor Manufacturing Company, Ltd., Hsinchu (TW)

(72) Inventors: Kuen-Yi Chen, Hsinchu City (TW); Yi-Hsuan Chen, Taoyuan City (TW); Yi Ching Ong, Hsinchu (TW); Kuo-Ching Huang, Hsinchu City (TW)

(21) Appl. No.: 19/269,113

(22) Filed: Jul. 15, 2025

Related U.S. Application Data
(62) Division of application No. 17/690,685, filed on Mar. 9, 2022.
(60) Provisional application No. 63/219,423, filed on Jul. 8, 2021.

(51) Int. Cl. H10B 53/30; H10B 53/20

(52) U.S. Cl. CPC H10B 53/30; H10B 53/20

(57) ABSTRACT

In some embodiments, the present disclosure relates to an integrated chip that includes one or more interconnect wires and vias arranged within one or more interconnect dielectric layers over a substrate. Further, a bottom electrode is disposed over the one or more interconnect wires and vias and comprises a first material having a first work function. A top electrode is disposed over the bottom electrode and comprises a second material having a second work function. The first material is different than the second material, and the first work function is different than the second work function. An anti-ferroelectric layer is disposed between the top and bottom electrodes.

### REFERENCE TO RELATED APPLICATIONS

This Application is a Divisional of U.S. application Ser. No. 17/690,685, filed on Mar. 9, 2022, which claims the benefit of U.S. Provisional Application No. 63/219,423, filed on Jul. 8, 2021. The contents of the above-referenced Patent Applications are hereby incorporated by reference in their entirety.

### BACKGROUND

Many modern day electronic devices include non-volatile memory. Non-volatile memory is electronic memory that is able to store data in the absence of power. A promising candidate for the next generation of non-volatile memory is ferroelectric random-access memory (FeRAM). FeRAM has a relatively simple structure and is compatible with complementary metal-oxide-semiconductor (CMOS) logic fabrication processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip comprising an anti-ferroelectric tunnel junction (ATJ) structure having an anti-ferroelectric layer and a non-polar layer arranged between top and bottom electrodes.

FIG. 2 illustrates a cross-sectional view of some other embodiments of an integrated chip comprising an ATJ structure having an anti-ferroelectric layer and a non-polar layer arranged between top and bottom electrodes.

FIG. 3 illustrates a plot of some embodiments of a hysteresis curve associated with the ATJ structures of FIGS. 1 and/or 2.

FIG. 4 illustrates a cross-sectional view of some embodiments of an integrated chip comprising an ATJ structure coupled to a bit-line and a semiconductor device.

FIG. 5A illustrates a cross-sectional view of some embodiments of an integrated chip comprising a memory structure having a ferroelectric tunnel junction.

FIGS. 5B-5C illustrates graphical representations of energy barrier diagrams showing exemplary operation of the integrated chip of FIG. 5A.

FIGS. 6A-6F illustrate some additional embodiments of a memory circuit having a ferroelectric tunnel junction configured to store multiple data levels.

FIG. 7A illustrates a cross-sectional view of some alternative embodiments of the integrated chip of FIG. 5A in which the memory structure further comprises a second intermediate electrode and a second non-polar layer stacked between the ferroelectric layer and the top electrode.

FIG. 7B illustrates a cross-sectional view of some alternative embodiments of the integrated chip of FIG. 5A in which the ferroelectric layer is stacked between the bottom electrode and the intermediate electrode, and the non-polar layer is stacked between the intermediate electrode and the top electrode.

FIG. 8 illustrates a cross-sectional view of some embodiments of an integrated chip comprising a memory structure having a ferroelectric tunnel junction and a ferroelectric layer having a non-uniform oxygen distribution.

FIGS. 9A-9E illustrate cross-sectional views of some alternative embodiments of the integrated chip of FIG. 8 in which the memory structure is varied.

FIG. 10A illustrates a cross-sectional view of some alternative embodiments of the integrated chip of FIG. 5A in which the ferroelectric layer has a varying thickness throughout a width of the ferroelectric layer.

FIG. 10B illustrates a graphical representation of the dipole-switching distribution of the integrated chip of FIG. 10A.

FIGS. 10C-10F illustrate cross-sectional views corresponding to the different memory levels of FIG. 10B.

FIG. 11A illustrates a cross-sectional view of some alternative embodiments of the integrated chip of FIG. 5A in which the ferroelectric layer has a protrusion portion extending from a central portion of the ferroelectric layer.

FIG. 11B illustrates a graphical representation of the dipole-switching distribution of the integrated chip of FIG. 11A.

FIG. 12 illustrates a cross-sectional view of some alternative embodiments of the integrated chip of FIG. 11A in which the ferroelectric layer comprises a plurality of protrusion portions having different thicknesses.

FIG. 13 illustrates a cross-sectional view of some embodiments of an integrated chip in which a one-transistor one-capacitor (1T1C) memory structure comprises a memory structure having a ferroelectric tunnel junction.

FIGS. 14-19 illustrate cross-sectional views of some embodiments of a method of forming an integrated chip comprising an ATJ structure having an anti-ferroelectric layer and a non-polar layer arranged between top and bottom electrodes.

FIG. 20 illustrates a flow diagram of some embodiments of a method corresponding to the method illustrated in FIGS. 14-19.

FIGS. 21-29 illustrate a series of cross-sectional views of some embodiments of a method for forming an integrated chip in which a 1T1C memory structure comprises a memory structure having a ferroelectric tunnel junction.

FIG. 30 illustrates a flowchart of some embodiments of the method of FIGS. 21-29.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A ferroelectric random-access memory (FeRAM) device includes a ferroelectric layer arranged between top and bottom electrodes. FeRAM devices are configured to store data values based on a process of reversible switching between polarization states because the ferroelectric layer's crystal structure is capable of changing when an electric field is present. For example, in a FeRAM cell, a negative voltage bias applied to a ferroelectric layer may induce atoms to shift into a first crystal structure orientation, which has a first resistance indicating a first data value (e.g., a logical ‘1’), whereas a positive voltage bias applied to the ferroelectric layer may induce atoms to shift into a second crystal structure orientation, which has a second resistance indicating a second data value (e.g., a logical ‘0’).

To perform a read operation that reads a data state from the ferroelectric layer, a read voltage is applied across the ferroelectric layer through the top and bottom electrodes. The read voltage causes a polarization switching current to be generated, which is dependent upon a data state stored in the ferroelectric layer. By comparing the polarization switching current to a reference voltage, a sense amplifier can read a data state stored in the ferroelectric layer. However, the read voltage may destroy the data state stored in the ferroelectric layer. For example, if a logical ‘1’ is read, after the read voltage is applied, the logical ‘1’ may switch to a logical ‘0.’ Thus, the read operation may destroy the stored data state. Because the read operation destroys a stored data state, a read cycle will take a longer time since it will restore the data state to its original value after the read operation is completed.

Further, some FeRAM devices comprise an “anti-ferroelectric” layer instead of a ferroelectric layer to increase the longevity of the FeRAM device because a smaller voltage is needed to switch the data value of an anti-ferroelectric material than of a ferroelectric material. However, the prefix “anti” in the “anti-ferroelectric” layer indicates that anti-ferroelectric layers are typically volatile, meaning when no voltage bias is applied across the top and bottom electrodes, the anti-ferroelectric layer does not keep the first or second crystal structure orientation. The volatility of the anti-ferroelectric layer is indicated in a hysteresis curve that shows the electric polarization of the anti-ferroelectric layer versus electric field applied across the anti-ferroelectric layer. Because the polarization equals zero or about zero when the electric field is zero comes from the negative and positive electric field directions, the anti-ferroelectric layer does not have a distinguishable polarization state when no voltage bias is applied across the anti-ferroelectric layer, making the memory type of an anti-ferroelectric layer volatile.

Various embodiments of the present disclosure relate to an anti-ferroelectric tunnel junction (ATJ) structure that comprises an anti-ferroelectric layer and a non-polar layer arranged between top and bottom electrodes having different work functions. Because the top and bottom electrodes have different work functions than one another, a flatband voltage is created, thereby shifting the hysteresis curve of the ATJ structure and creating a non-volatile ATJ structure. Further, the non-polar layer contributes to the built-in bias through an asymmetrical charge screening effect. Additionally, the anti-ferroelectric layer in the ATJ structure of this disclosure is substantially thin (e.g., less than 5 nanometers) which improves the detectability of the polarization states while also saving space of the overall device in the vertical direction. The anti-ferroelectric layer comprises pure zirconium oxide or some other suitable anti-ferroelectric material with a low crystallization temperature. By having a low crystallization temperature, the anti-ferroelectric layer can be formed and integrated into a back-end-of-line (BEOL) structure that has a low thermal annealing temperatures (e.g., less than 400 degrees Celsius) without damaging the interconnect structure.

Further embodiments of the present disclosure relate to a memory structure from which data is able to be read without altering the data (e.g., non-destructively). In some embodiments, the memory structure comprises a ferroelectric layer vertically stacked between a bottom electrode and a top electrode. A reading voltage applied across the top electrode and bottom electrode will cause charge carriers (e.g., electrons) to accumulate along the bottom electrode. The memory structure comprises a non-polar layer vertically stacked between the bottom electrode and the ferroelectric layer that screens charge carriers from the applied voltage, causing some charge carriers to quantum mechanically tunnel through the non-polar layer, forming a charge imbalance between the non-polar layer and the ferroelectric layer. The charge imbalance has a value that is dependent upon a remanent polarization on the ferroelectric layer, and causes an electric field to form that changes a shape of an energy barrier provided by the ferroelectric layer. The change in shape of the energy barrier allows for different read currents to quantum mechanically tunnel through the ferroelectric layer depending upon a data stated stored in the ferroelectric layer. By having different read currents tunnel through the ferroelectric layer depending upon a data state stored in the ferroelectric layer, a data state of the ferroelectric layer can be read in a non-destructive manner. Since the read operation is non-destructive, the memory structure has better endurance, better retention, and lower power operation as compared to the FeRAM device.

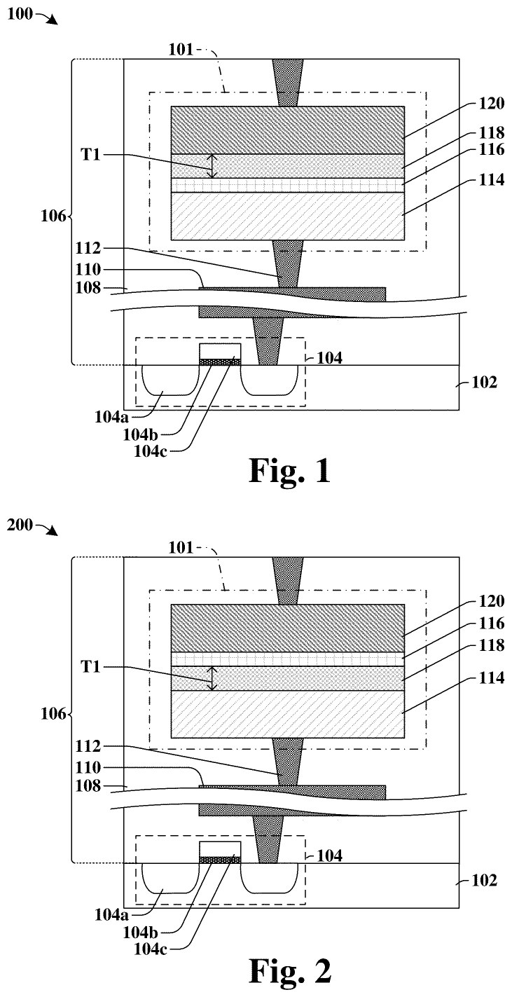

FIG. 1 illustrates a cross-sectional view 100 of some embodiments of an integrated chip comprising an anti-ferroelectric tunnel junction (ATJ) structure.

The integrated chip in cross-sectional view 100 of FIG. 1 includes an interconnect structure 106 arranged over a substrate 102. In some embodiments, the interconnect structure 106 comprises a network of interconnect wires 110 and interconnect vias 112 arranged within an interconnect dielectric structure 108. In some embodiments, the interconnect structure 106 is arranged over and coupled to a semiconductor device 104 arranged on and/or within the substrate 102. In some embodiments, the semiconductor device 104 is an access transistor and comprises source/drain regions 104a within the substrate 102, a gate electrode 104c arranged over the substrate 102 and between the source/drain regions 104a, and a gate dielectric layer 104b arranged between the substrate 102 and the gate electrode 104c. In FIG. 1, the semiconductor device 104 is illustrated as a planar metal-oxide-semiconductor field effect transistor (MOSFET). It will be appreciated that the semiconductor device 104 may be or comprise some other type of transistor device such as a finFET, a gate all around FET, or some other suitable device.

The integrated chip of FIG. 1 further includes an anti-ferroelectric tunnel junction (ATJ) structure 101 arranged within the interconnect structure 106 and coupled to the semiconductor device 104. In some embodiments, the ATJ structure 101 comprises a bottom electrode 114, a non-polar layer 116 arranged over the bottom electrode 114, an anti-ferroelectric layer 118 arranged over the non-polar layer 116, and a top electrode 120 arranged over the anti-ferroelectric layer 118. In some embodiments, the bottom electrode 114 is arranged on and coupled to one of the interconnect wires 110 or one of the interconnect vias 112, and the top electrode 120 is arranged below and coupled to one of the interconnect wires 110 or one of the interconnect vias 112. In some embodiments, data values (e.g., a logical ‘1’ or a logical ‘0’) are written to and read from the ATJ structure 101 depending on the signals (e.g., current, voltage) applied across the bottom and top electrodes 114, 120.

In some such embodiments, data is stored in the anti-ferroelectric layer 118, which comprises an anti-ferroelectric material. The anti-ferroelectric material has ferroelectric-like properties because it is configured to change crystal structures upon the application of different voltage biases. The switchable crystal structure of the anti-ferroelectric layer 118 corresponds to a different resistance of the ATJ structure 101. Therefore, during a read operation, the resistance of the ATJ structure 101 during the application of a read voltage corresponds to a certain crystal structure of the anti-ferroelectric layer 118, which ultimately corresponds to a certain data value (e.g., a logical ‘1’ or a logical ‘0’) stored in the ATJ structure 101. The ATJ structure 101 is non-volatile when there is a built-in bias across the anti-ferroelectric layer 118. Therefore, when no voltage is applied across the top and bottom electrodes 120, 114, there is still a built-in bias across the anti-ferroelectric layer 118 to maintain its crystal structure and thus, stored data value (e.g., a logical ‘1’ or a logical ‘0’). The non-volatility of the ATJ structure 101 conserves power and increases the applications that the ATJ structure 101 can be used in.

In some embodiments, the non-polar layer 116 comprises a non-polar material that has a dielectric constant greater than about 8. In some embodiments, the non-polar layer 116 is configured to create an asymmetrical screening effect to contribute to the built-in bias across the anti-ferroelectric layer 118. Thus, the non-polar layer 116 prevents complete charge screening (e.g., a zero net charge) between the anti-ferroelectric layer 118 and the bottom electrode 114. In some embodiments, dipole moments form within the non-polar layer 116 which improves the distinguishability of the read current during a read operation, and thus, improves the reliability of the device. If the dielectric constant of the non-polar layer 116 is less than about 8, then the non-polar layer 116 cannot be formed at a low thickness while also providing the asymmetrical screening effect, which would degrade the reliability of the device.

The bottom electrode 114 comprises a first material having a first work function, and the top electrode 120 comprises a second material having a second work function. The first material of the bottom electrode 114 is different than the second material of the top electrode 120 such that the first work function is different than the second work function. The difference between the first and second work functions also creates a built-in bias in the ATJ structure 101 such that the ATJ structure 101 is non-volatile. By using the non-polar layer 116 and the difference in work functions between the top and bottom electrodes 120, 114, the tunneling current within the ATJ structure 101 is increased which improves the differentiability between data states stored in the ATJ structure 101. In some embodiments, the absolute value of the difference between the first work function of the bottom electrode 114 and the second work function of the top electrode 120 is greater than or equal to about 0.3 eV to ensure that a built-in bias is formed such that the device is non-volatile. In some embodiments, when the non-polar layer 116 is arranged between the anti-ferroelectric layer 118 and the bottom electrode 114, the first work function of the bottom electrode 114 is greater than the second work of the top electrode 120 such that the dipole moment within the non-polar layer 116 and the built-in bias across the top and bottom electrodes 120, 114 are in the same direction to improve the tunneling current, and thus, to improve the differentiability between data states store in the ATJ structure 101.

To reduce the magnitude of the voltage required to read from and write onto the anti-ferroelectric layer 118 while also having a large memory window to easily distinguish between data states, the ferroelectric layer 118 has a thickness T1 that is substantially small. In some such embodiments, the thickness T1 is in a range of between approximately 0.5 nanometers and approximately 5 nanometers. Further, the anti-ferroelectric layer 118 has a crystallization temperature that is less than an annealing temperature used to form the interconnect structure 106. The annealing temperature of the interconnect structure 106 is limited to prevent metal diffusion in the interconnect structure 106. Therefore, the anti-ferroelectric layer 118 may be crystallized during formation within the interconnect structure 106 without damaging the interconnect structure 106 through excessive heat. For example, in some embodiments, the crystallization temperature of the anti-ferroelectric layer 118 is in a range of between, for example, approximately 50 degrees Celsius and approximately 400 degrees Celsius. If the crystallization temperature of the anti-ferroelectric layer 118 were greater than 400 degrees, then metal diffusion and/or delamination may occur within the interconnect structure 106 which would result in an unreliable and/or non-functioning device. In other words, the crystallization temperature of the anti-ferroelectric layer 118 is not greater than a maximum temperature that the interconnect structure 106 can tolerate without damage (e.g., a maximum temperature value that the interconnect structure is formed at). Therefore, because of its low crystallization temperature (e.g., less than approximately 400 degrees Celsius) and small thickness (e.g., T1 is less than approximately 5 nanometers), the anti-ferroelectric layer 118 comprises, in some embodiments, zirconium oxide, lead zirconium oxide, polyvinylidene fluoride, zirconium-rich (e.g., greater than 70 percent zirconium) hafnium zirconium oxide, or some other suitable anti-ferroelectric material.

FIG. 2 illustrates a cross-sectional view 200 of some other embodiments of an integrated chip comprising an ATJ structure that includes the anti-ferroelectric layer and the non-polar layer.

In some embodiments, the non-polar layer 116 is arranged above the anti-ferroelectric layer 118 and directly between the anti-ferroelectric layer 118 and the top electrode 120. In some such embodiments, when the non-polar layer 116 is arranged between the top electrode 120 and the anti-ferroelectric layer 118, the first work function of the bottom electrode 114 is less than the second work function of the top electrode 120 such that the dipole moment within the non-polar layer 116 and the built-in bias across the top and bottom electrodes 120, 114 are in the same direction to improve the tunneling current, and thus, to improve the differentiability between data states store in the ATJ structure 101.

In some embodiments, the non-polar layer 116 comprises, for example, aluminum oxide, silicon dioxide, tantalum oxide, or some other suitable dielectric material that has a dielectric constant greater than 8. In some embodiments, the non-polar layer 116 has a thickness in a range of between, for example, approximately 0.1 nanometers and approximately 2 nanometers. Thus, in some embodiments, the non-polar layer 116 may be thicker than, thinner than, or about equal in thickness to the anti-ferroelectric layer 118. In some embodiments, the top electrode 120 comprises tantalum nitride titanium nitride, platinum, ruthenium, indium tin oxide, indium gallium zinc oxide, or some other suitable conductive material. In some embodiments, the bottom electrode 114 comprises a different material than the top electrode 120 and may comprise, for example, tantalum nitride titanium nitride, platinum, ruthenium, indium tin oxide, indium gallium zinc oxide, or some other suitable conductive material. In some embodiments, the bottom and top electrodes 114, 120 may each have a thickness in a range of, for example, approximately 10 nanometers and approximately 100 nanometers.

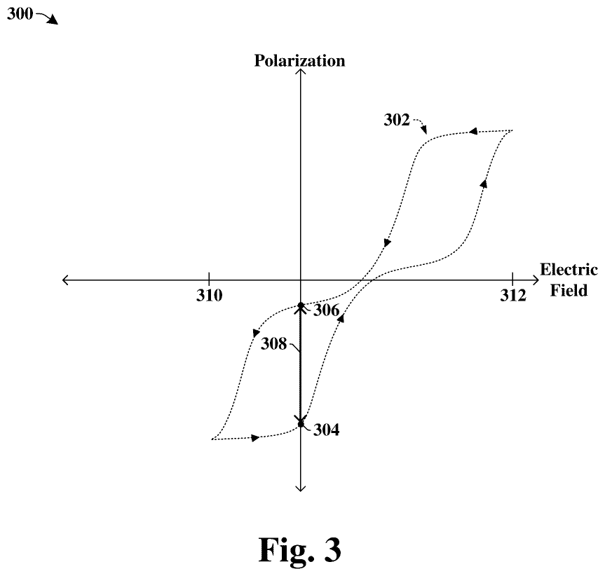

FIG. 3 illustrates a plot 300 of some embodiments of a hysteresis curve that may correspond to the ATJ structures of FIGS. 1 and 2.

The ATJ structures of FIGS. 1 and 2 are each configured to produce a hysteresis curve 302 that displays the polarization of the anti-ferroelectric layer (e.g., 118 of FIG. 1) versus an electric field applied to across the top and bottom electrodes (e.g., 120, 114 of FIG. 1). In some embodiments, the hysteresis curve 302 is formed by collecting polarization data values of the anti-ferroelectric layer (e.g., 118 of FIG. 1) while increasing an electric field that is applied to the anti-ferroelectric layer (e.g., 118 of FIG. 1) from zero to a first positive electric field value 312, decreasing the applied electric field from the first positive electric field value 312 to a first negative electric field value 310, and increasing the applied electric field from the first negative electric field value 310 to zero.

When the electric field equals zero, the hysteresis curve 302 has two different polarization values: a first polarization value 306 and a second polarization value 304. This means that when no electric field is applied to the ATJ structure (e.g., 101 of FIG. 1), the anti-ferroelectric layer (e.g., 118 of FIG. 1) has either the first polarization value 306 or the second polarization value 304. In some embodiments, because the hysteresis curve 302 is shifted to the right, the first and second polarization values 306, 304 are each negative. In some embodiments, the first polarization value 306 indicates that the anti-ferroelectric layer (e.g., 118 of FIG. 1) has a first crystal structure that corresponds to a first data value (e.g., a logical ‘1’). In some embodiments, the second polarization value 304 indicates that the anti-ferroelectric layer (e.g., 118 of FIG. 1) has a second crystal structure that corresponds to a second data value (e.g., a logical ‘0’).

A polarization difference value 308 is the difference between the first polarization value 306 and the second polarization value 304. The polarization difference value 308 is also known as the memory window of the ATJ structure 101. The larger the polarization difference value 308 is, the easier it is to distinguish which memory state the ATJ structure (e.g., 101 of FIG. 1) is storing: either the first data value (e.g., a logical ‘1’) or the second data value (e.g., a logical ‘0’). The hysteresis curve 302 is shift to the right in FIG. 3 such that the polarization difference value 308 is large because of the presence of built-in bias within the ATJ structure (e.g., 101 of FIG. 1) which makes the ATJ structure (e.g., 101 of FIG. 1) non-volatile. The shift in the hysteresis curve 302 occurs at least because the absolute value of the difference between the first work function of the bottom electrode (114 of FIG. 1) and the second work function of the top electrode (120 of FIG. 1) is greater than or equal to about 0.3 eV. If the aforementioned difference in work functions were less than 0.3 eV, then the hysteresis curve 302 would not shift or would not shift enough to the right, which would result in a volatile device or at least a device in which the different data states are indistinguishable when no voltage bias is applied to the device. Thus, by using different work functions for the top and bottom electrodes (e.g., 120, 114 of FIG. 1), the distinguishability between the first and second data values is increased, which increases the reliability of the ATJ structure (e.g., 101 of FIG. 1).

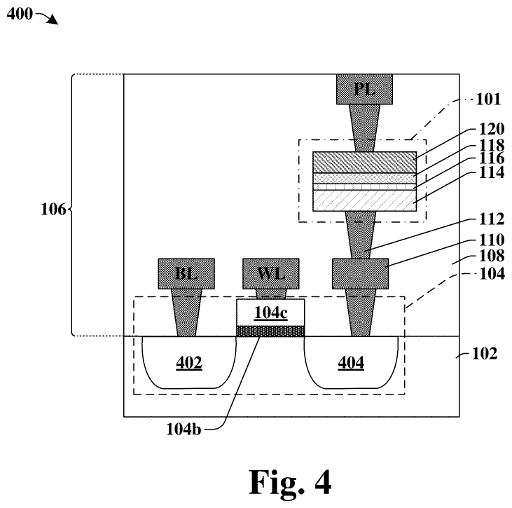

FIG. 4 illustrates a cross-sectional view 400 of yet some other embodiments of an integrated chip comprising an ATJ structure.

The integrated chip of FIG. 4 comprises the ATJ structure 101 coupled to the semiconductor device 104 and a plate-line PL. More specifically, in some embodiments, the bottom electrode 114 of the ATJ structure 101 is coupled to a drain region 404 of the semiconductor device 104, whereas the top electrode 120 of the ATJ structure 101 is coupled to the plate-line PL. In some embodiments, a bit-line BL is coupled to a source region 402 of the semiconductor device 104. In some embodiments, a word-line WL is coupled to the gate electrode 104c of the semiconductor device 104. When the ATJ structure 101 is accessed through signals (e.g., current, voltage) sent to the plate-line PL, the word-line WL, and the bit-line BL, a first or second data state can be written to or read from the ATJ structure 101 through the anti-ferroelectric layer 118. When the signals are stopped, the ATJ structure 101 maintains the data state because of the built-in bias provided by the top and bottom electrodes 120, 114 as well as the non-polar layer 116, thereby making the ATJ structure 101 non-volatile.

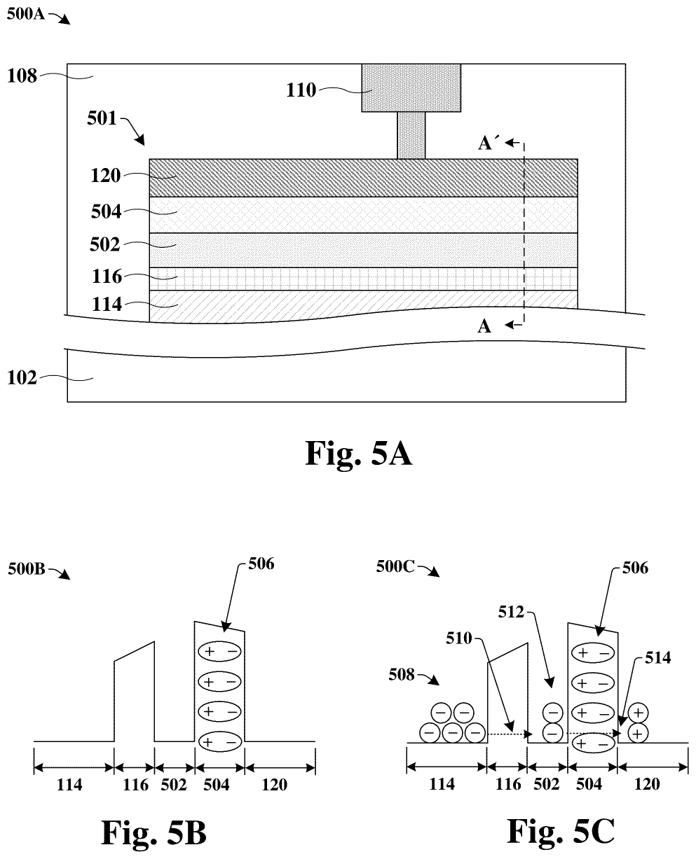

FIG. 5A illustrates a cross-sectional view 500A of some embodiments of a memory structure 501 having a ferroelectric tunnel junction. The memory structure 501 is disposed within an interconnect dielectric structure 108 that overlies a substrate 102. The memory structure 501 comprises a bottom electrode 114 vertically stacked with an intermediate electrode 502 and a top electrode 120. A non-polar layer 116 is vertically stacked between the bottom electrode 114 and the intermediate electrode 502, and a ferroelectric layer 504 is vertically stacked between the intermediate electrode 502 and the top electrode 120. One or more interconnect wires 110 may contact the bottom electrode 114 and/or the top electrode 120 to apply voltage across the memory structure 501 and/or to read output currents across the memory structure 501. In some embodiments, a semiconductor device (not shown) that is coupled to the memory structure 501 may be disposed on and within the substrate 102 to access a data state of the memory structure 501.

By appropriately biasing the memory structure 501, a remanent polarization of the ferroelectric layer 504 may be changed between different data states. For example, in some embodiments, applying a first voltage having a positive polarity and a magnitude in excess of a coercive voltage of the memory structure 501 across the ferroelectric layer 504 may set a first data state. Further, applying a second voltage having a second polarity opposite the first polarity and a magnitude in excess of a coercive voltage of the memory structure 501 across the ferroelectric layer 504 may set a second data state. Because the remanent polarization may be electrically measured, the remanent polarization may be employed to represent a bit of data, and thus the ferroelectric layer 504 is configured to store a data state (e.g., a binary “1” or a binary “0”).

During operation, the non-polar layer 116 may screen charges from a reading voltage applied to the memory structure 501. By screening charges from the reading voltage, a charge imbalance is generated along an interface between the intermediate electrode 502 and the ferroelectric layer 504. The charge imbalance will have a value that is dependent upon a remanent polarization of the ferroelectric layer 504. The charge imbalance causes an electric field to form that changes a shape of an energy barrier provided by the ferroelectric layer 504. The change in shape of the energy barrier allows for different read currents to quantum mechanically tunnel through the ferroelectric layer 504. Because the different read currents depend upon the remanent polarization of the ferroelectric layer, the different read currents correspond to a data state stored in the ferroelectric layer 504. By having different read currents generated based upon a data state stored in the ferroelectric layer 504, a data state stored in the ferroelectric layer 504 can be read in a non-destructive manner. Since the read operation is non-destructive, the memory structure has good endurance, good data retention, and low power.

FIGS. 5B-5C illustrate graphical representations of energy barrier diagrams showing exemplary operation of the memory structure of FIG. 5A.

FIG. 5B illustrates an exemplary energy barrier diagram 500B taken along cross-sectional line A-A′ of FIG. 5A. As shown in exemplary energy barrier diagram 500B, the non-polar layer 116 provides an energy barrier that separates the bottom electrode 114 from the intermediate electrode 502. The ferroelectric layer 504 also provides an energy barrier that separates the intermediate electrode 502 from the top electrode 120. Within the ferroelectric layer 504, charges are arranged in a dipole configuration 506 that denotes a data state.

As shown in energy barrier diagram 500C of FIG. 5C, when a read voltage is applied across the memory structure a first plurality of charge carriers 508 (e.g., electrons) build up along the bottom electrode 114. The first plurality of charge carriers 508 are unable to classically overcome the energy barrier of the non-polar layer 116. However, waveforms of the first plurality of charge carriers 508 extend through the non-polar layer 116, so that the first plurality of charge carriers 508 have a non-zero probability of quantum mechanically tunneling through the non-polar layer 116 to the intermediate electrode 502. Therefore, some of the first plurality of charge carriers 508 are able to tunnel 510 through the non-polar layer 116 so that a second plurality of charge carriers 512 build-up on the intermediate electrode 502 resulting in a non-zero net charge along an interface between the intermediate electrode 502 and the ferroelectric layer 504.

The non-zero net charge will generate an electric field that will modify a shape of the energy barrier provided by the ferroelectric layer 504 depending on a data state stored in the ferroelectric layer 504. The different shapes of the energy barrier provided by the ferroelectric layer 504 will allow for different read currents 514 to tunnel through the ferroelectric layer 504. The different read currents 514 are representative of different data states. Because the different read currents 514 are representative of the different data states, but are not large enough to switch a dipole of the ferroelectric layer 504, a data state to be non-destructively read from the ferroelectric layer 504.

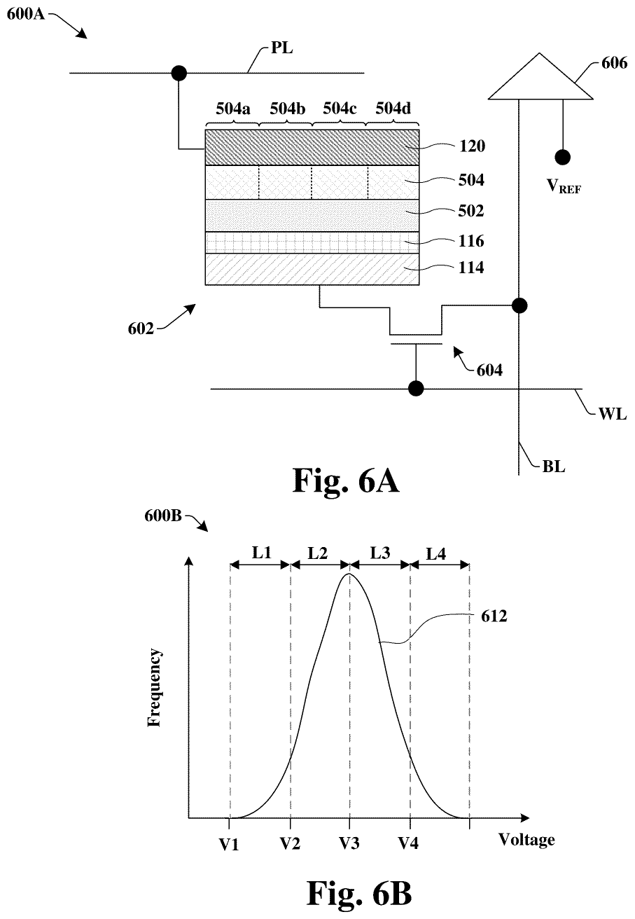

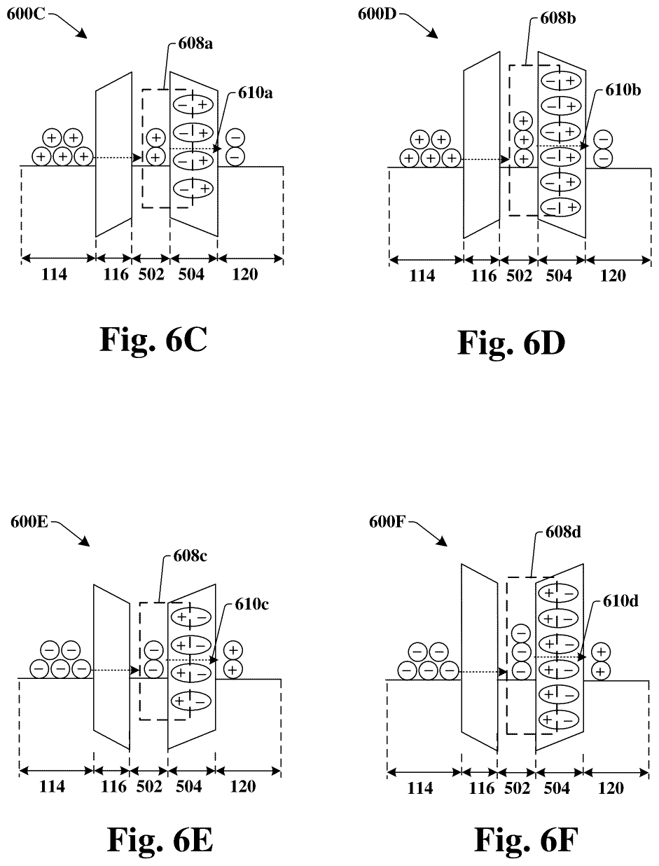

FIG. 6A illustrates a cross-sectional view of some additional embodiments of a memory circuit 600A having a memory structure comprising a ferroelectric tunnel junction configured to store multiple data levels.

The memory circuit 600A comprises a memory structure 602 having a non-polar layer 116 disposed over a bottom electrode 114. An intermediate electrode 502 is disposed between the non-polar layer 116 and a ferroelectric layer 504. A top electrode 120 is arranged on the ferroelectric layer 504. In some embodiments, the ferroelectric layer 504 may comprise a plurality of different ferroelectric domains 504a-504d. The different ferroelectric domains 504a-504d may respectively have dipoles that are configured to switch at different coercive voltages so that different coercive voltages cause the ferroelectric layer 504 to have different strengths of remanent polarization. In some embodiments, the different ferroelectric domains 504a-504d may have different grain sizes, defect amounts, build in field distributions, or the like.

In some embodiments, the top electrode 120 is coupled to a plate line PL, while the bottom electrode 114 is coupled to a drain terminal of an access transistor 604. The access transistor 604 comprises a gate electrode coupled to word-line WL and a source terminal coupled to a bit-line BL. The bit-line BL may be further coupled to a sense amplifier 606 that is configured to receive a read current that is indicative of a data state stored in the ferroelectric layer 504.

The different strengths of remanent polarization, in conjunction with the non-polar layer 116, may allow for good control over a plurality of different read currents to be generated from the ferroelectric layer 504 depending upon a data state stored in the ferroelectric layer 504. The plurality of different read currents allow for multiple data levels to be stored in the ferroelectric layer 504. For example, FIG. 6B illustrates a graphical representation 600B of the dipole-switching distribution of the integrated chip of FIG. 6A. Curve 612 corresponds to a plurality of ranges of coercive voltages of the memory structure 602. During operation of the memory structure 602, a bit of data is stored in the ferroelectric layer 504 using the remanent polarization of the ferroelectric layer 504 to represent the bit. In some embodiments, the different ferroelectric domains 504a-504d of the ferroelectric layer 504 may have different remanent polarizations, such that the remanent polarizations of respective ferroelectric domains 504a-504d are used to represent different memory levels respectively corresponding to a plurality of bits.

For example, to program a first memory level L₁ within the ferroelectric layer 504, a first set voltage or a reset voltage having a value between V1 and V2 is applied across the memory structure to switch the dipole of a first ferroelectric domain (e.g., 504a) of the ferroelectric layer 504, setting the remanent polarization of the ferroelectric layer 504 to a first value corresponding to a first memory level L₁. In some embodiments, the first memory level L₁ may correspond to a first pair of data states (e.g., ‘00’). To program a second memory level L₂ within the ferroelectric layer 504, a second set voltage or a reset voltage having a value between V2 and V3 is applied across the memory structure to switch the dipole of a second ferroelectric domain (e.g., 504b) of the ferroelectric layer 504, setting the remanent polarization of the ferroelectric layer 504 to a second value corresponding to a second memory level L₂. In some embodiments, the second memory level L₂ may correspond to a second pair of data states (e.g., ‘01’). To program a third memory level L₃ within the ferroelectric layer 504, a third set voltage or a reset voltage having a value between V3 and V4 is applied across the memory structure to switch the dipole of a third ferroelectric domain (e.g., 504c) of the ferroelectric layer 504, setting the remanent polarization of the ferroelectric layer 504 to a third value that corresponds to a third memory level L₃. In some embodiments, the third memory level L₃ may correspond to a third pair of data states (e.g., ‘10’). To program a fourth memory level L₄ within the ferroelectric layer 504, a fourth set voltage or a reset voltage having a value of greater than or equal to V4 is applied across the memory structure to switch the dipole of a fourth ferroelectric domain (e.g., 504d) of the ferroelectric layer 504, setting the remanent polarization of the ferroelectric layer 504 to a fourth memory level L₄. In some embodiments, the fourth memory level L4 may correspond to a fourth pair of data states (e.g., ‘11’).

FIGS. 6C-6F illustrate exemplary energy barrier diagrams 600C-600F showing various embodiments of the memory structure of FIG. 6A having different memory levels.

In the exemplary energy barrier diagram 600C of FIG. 6C, the ferroelectric layer 504 has a relatively small remanent polarization that is orientated along a first direction. During a read operation, a read voltage will cause holes to tunnel through the non-polar layer 116 so as to form a plurality of holes that accumulate on the intermediate electrode 502. The plurality of holes cause a first non-zero net charge 608a along an interface between the intermediate electrode 502 and the ferroelectric layer 504 to form a first barrier having a first shape and/or height. The first barrier results in a first read current 610a tunneling through the ferroelectric layer 504. The first read current 610a is associated with the first memory level (e.g., L₁).

In the exemplary modified band diagram 600D of FIG. 6D, the ferroelectric layer 504 has a relatively large remanent polarization that is orientated along the first direction. During a read operation, a read voltage will cause holes to tunnel through the non-polar layer 116 so as to form a plurality of holes that accumulate on the intermediate electrode 502. The plurality of holes cause a second non-zero net charge 608b along an interface between the intermediate electrode 502 and the ferroelectric layer 504. The second non-zero net charge 608b will generate a second net electric field that will cause the ferroelectric layer 504 to form a second barrier having a second shape and/or height. The second barrier results in a second read current 610b tunneling through the ferroelectric layer 504. The second read current 610b is associated with a second memory level (e.g., L₂).

In the exemplary modified band diagram 600E of FIG. 6E, the ferroelectric layer 504 has a relatively small remanent polarization that is orientated along a second direction. During a read operation, a read voltage will cause electrons to tunnel through the non-polar layer 116 so as to form a plurality of electrons that accumulate on the intermediate electrode 502. The plurality of electrons cause a third non-zero net charge 608c along an interface between the intermediate electrode 502 and the ferroelectric layer 504. The third non-zero net charge 608c will generate a third net electric field that will cause the ferroelectric layer 504 to form a third barrier having a third shape and/or height. The third barrier results in a third read current 610c tunneling through the ferroelectric layer 504. The third read current 610c is associated with a third memory level (e.g., L₃).

In the exemplary modified band diagram 600F of FIG. 6F, the ferroelectric layer 504 has a relatively large remanent polarization that is orientated along the second direction. During a read operation, a read voltage will cause electrons to tunnel through the non-polar layer 116 so as to form a plurality of electrons that accumulate on the intermediate electrode 502. The plurality of electrons cause a fourth non-zero net charge 608d along an interface between the intermediate electrode 502 and the ferroelectric layer 504. The fourth non-zero net charge 608d will generate a fourth net electric field that will cause the ferroelectric layer 504 to form a fourth barrier having a fourth shape and/or height. The fourth barrier results in a fourth read current 610d tunneling through the ferroelectric layer. The fourth read current 610d is associated with a fourth memory level (e.g., L₄).

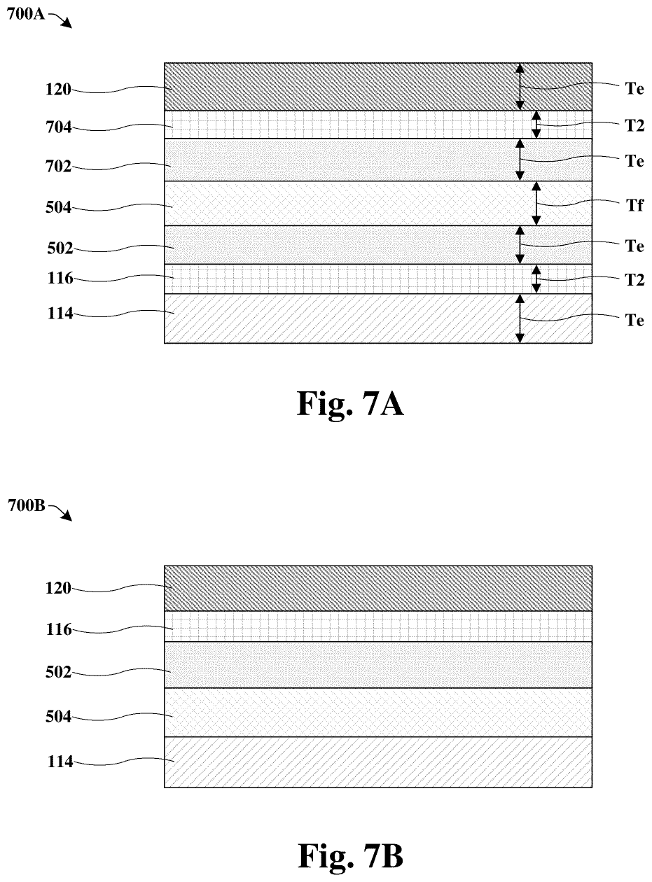

FIG. 7A illustrates a cross-sectional view 700A of some alternative embodiments of the integrated chip of FIG. 5A in which the memory structure further comprises a second intermediate electrode 702 and a second non-polar layer 704 stacked between the ferroelectric layer 504 and the top electrode 120. The second intermediate electrode 702 is stacked between the ferroelectric layer 504 and the second non-polar layer 704. In some embodiments, the intermediate electrode 502 may provide mechanical stress to the ferroelectric layer 504 to promote orthorhombic phase crystalline growth in the ferroelectric layer 504. This improves the remanent polarization of the ferroelectric layer 504, hence improving performance of the memory structure. In some embodiments, by including the second intermediate electrode 702, more mechanical stress is applied to the ferroelectric layer 504. In some embodiments, the mechanical stress may comprise tensile stress. In some embodiments, by including the second non-polar layer 704, standby power is reduced and sneak current is prevented without including a selector device, hence improving performance and saving costs.

In some embodiments, the ferroelectric layer 504 has a thickness Tf ranging from approximately 0.1 nanometers to approximately 4 nanometers, from approximately 0.1 nanometers to approximately 2 nanometers, from approximately 2 nanometers to approximately 4 nanometers, or some other suitable value. In some embodiments, if the thickness Tf is too large (e.g., more than approximately 4 nanometers), the read current may be unable to sufficiently pass through the memory structure, negatively affecting the effectiveness of read operations. In some embodiments, if the thickness Tf is too small (e.g., less than approximately 0.1 nanometers), the ferroelectric layer 504 may provide an insufficient amount of remanent polarization to store data reliably.

In some embodiments, the non-polar layer 116 and the second non-polar layer 704 respectively have a thickness T2 ranging from approximately 0.1 nanometers to approximately 1 nanometer, from approximately 0.1 nanometers to approximately 0.5 nanometers, from approximately 0.5 nanometers to approximately 1 nanometer, or some other suitable value. In some embodiments, if the thickness T2 is too large (e.g., more than approximately 1 nanometer), a read current may be unable to sufficiently tunnel through the memory structure, negatively affecting the effectiveness of read operations. In some embodiments, if the thickness T2 is too small (e.g., less than approximately 0.1 nanometers), the non-polar layer 116 will not provide for a sufficient energy barrier that enables a non-zero net charge along an interface with the ferroelectric layer 504. Without the non-zero net charge at the interface, the memory structure may be unable to output different levels of read currents, and hence the memory structure may be unable to output stored data states. In some embodiments, non-polar layer 116 and the second non-polar layer 704 have a same thickness. In some embodiments, non-polar layer 116 and the second non-polar layer 704 have different thicknesses.

In some embodiments, the bottom electrode 114, the intermediate electrode 502, the second intermediate electrode 702, and the top electrode 120 have respective thicknesses Te ranging from approximately 10 nanometers to approximately 100 nanometers, approximately 10 nanometers to approximately 50 nanometers, approximately 50 nanometers to approximately 100 nanometers, or some other suitable value. In some embodiments, the bottom electrode 114, the intermediate electrode 502, the second intermediate electrode 702, and the top electrode 120 have a same thickness. In some embodiments, the bottom electrode 114, the intermediate electrode 502, the second intermediate electrode 702, and/or the top electrode 120 have different thicknesses.

In some embodiments, the ferroelectric layer 504 is or comprises perovskite (e.g., CaTiO₃), rutile (e.g., TiO₂), hafnium zirconium oxide (e.g., HfZrO), and/or is doped with aluminum (e.g., Al), silicon (e.g., Si), lanthanum (e.g., La), scandium (e.g., Sc), calcium (e.g., Ca), barium (e.g., Ba), gadolinium (e.g., Gd), yttrium (e.g., Y), strontium (e.g., Sr), some other suitable element(s), or any combination of the foregoing to increase remanent polarization. In some embodiments, the ferroelectric layer 504 is in the orthorhombic crystalline phase. In some embodiments, the ferroelectric layer 504 is or comprises HfₓZr₁₋ₓO₂ with x ranging from 0 to 1. For example, the ferroelectric layer 504 may be or comprise Hf_{0.5}Zr_{0.5}O₂. In some embodiments, the ferroelectric layer 504 is or comprises aluminum nitride (e.g., AlN) doped with scandium (e.g., Sc) and/or some other suitable element(s). In some embodiments, the ferroelectric layer 504 is or comprises a material with oxygen vacancies. In some embodiments, the ferroelectric layer 504 is some other suitable ferroelectric material(s).

In some embodiments, the non-polar layer 116 and the second non-polar layer 704 may be or otherwise comprise, for example, silicon dioxide, aluminum oxide, tantalum oxide, or some other suitable non-polar material(s). In some embodiments, the non-polar layer 116 and the second non-polar layer 704 may have a dielectric constant greater than approximately 8. In some embodiments, if the dielectric constant of the non-polar layer 116 and the second non-polar layer 704 is too low (e.g., less than approximately 8), the non-polar layer 116 and the second non-polar layer 704 cannot be formed at the thickness T2, thus the read current may be unable to sufficiently pass through the memory structure, negatively affecting the effectiveness of read operations. In some embodiments, the non-polar layer 116 and the second non-polar layer 704 are or comprise a same material. In some embodiments, the non-polar layer 116 and the second non-polar layer 704 are or comprise different materials.

In some embodiments, the bottom electrode 114, the intermediate electrode 502, the second intermediate electrode 702, and the top electrode 120 may be or comprise, for example, tantalum nitride, titanium nitride, platinum, ruthenium, indium-tin-oxide (e.g., ITO), indium-gallium-zinc-oxide (e.g., IGZO), or some other suitable material(s). In some embodiments, the bottom electrode 114, the intermediate electrode 502, the second intermediate electrode 702, and the top electrode 120 may be or comprise, for example, a pure metal, a refractory metal nitride, a conductive oxide, or the like. In some embodiments, the bottom electrode 114, the intermediate electrode 502, the second intermediate electrode 702, and the top electrode 120 are or comprise a same material. In some embodiments, the bottom electrode 114, the intermediate electrode 502, the second intermediate electrode 702, and/or the top electrode 120 are or comprise different materials.

FIG. 7B illustrates a cross-sectional view 700B of some alternative embodiments of the integrated chip of FIG. 5A in which the ferroelectric layer 504 is stacked between the bottom electrode 114 and the intermediate electrode 502, and the non-polar layer 116 is stacked between the intermediate electrode 502 and the top electrode 120.

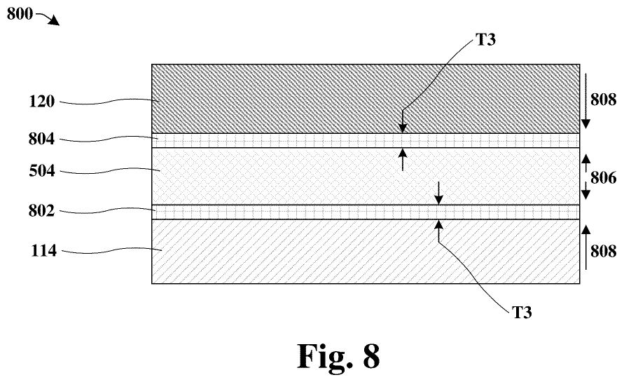

FIG. 8 illustrates a cross-sectional view 800 of some embodiments of an integrated chip comprising a memory structure having a ferroelectric tunnel junction and a ferroelectric layer 504 having a non-uniform oxygen distribution 806. A bottom electrode 114 is vertically stacked with a first non-polar layer 802, the ferroelectric layer 504, a second non-polar layer 804, and a top electrode 120. The ferroelectric layer 504 is disposed between the top electrode 120 and the bottom electrode 114. The first non-polar layer 802 is disposed between the ferroelectric layer 504 and the bottom electrode 114. The second non-polar layer 804 is disposed between the ferroelectric layer 504 and the top electrode 120.

In some embodiments, the non-uniform oxygen distribution 806 is such that an oxygen concentration of the ferroelectric layer 504 increases from a center of the ferroelectric layer 504 to a topmost surface of the ferroelectric layer 504. In some embodiments, the oxygen concentration of the ferroelectric layer 504 increases from a center of the ferroelectric layer 504 to a bottommost surface of the ferroelectric layer 504.

In some embodiments, the top electrode 120 and the bottom electrode 114 comprise a refractory nitride material having a non-uniform nitrogen distribution 808. In some embodiments, the non-uniform nitrogen distribution 808 is such that the top electrode 120 has a lower concentration of nitrogen near the ferroelectric layer 504 than an upper region of the top electrode 120, and the bottom electrode 114 has a lower concentration of nitrogen near the ferroelectric layer 504 than a lower region of the bottom electrode 114.

In some embodiments, during fabrication of the memory structure, the non-uniform nitrogen distribution 808 of the bottom electrode 114 and the non-uniform oxygen distribution 806 of the ferroelectric layer 504 may cause the first non-polar layer 802 to form without performing a separate deposition process. During a subsequently performed thermal process (e.g., a back-end-of-line (BEOL) thermal treatment), the lower nitrogen concentration near the ferroelectric layer 504 may cause the bottom electrode 114 to scavenge oxygen from the bottommost surface of the ferroelectric layer 504, leading to the formation of the first non-polar layer 802 (e.g., a non-polar oxide). Similarly, in some embodiments, during fabrication of the memory structure, the non-uniform nitrogen distribution 808 of the top electrode 120 and the non-uniform oxygen distribution 806 of the ferroelectric layer 504 may cause the second non-polar layer 804 to form without performing a separate deposition process. During a subsequently performed thermal process (e.g., a BEOL thermal treatment), the lower nitrogen concentration near the ferroelectric layer 504 may cause the top electrode 120 to scavenge oxygen from the topmost surface of the ferroelectric layer 504, leading to the formation of the second non-polar layer 804.

During operation, the first non-polar layer 802 and the second non-polar layer 804 may screen charges from a reading voltage applied to the memory structure. By screening charges from the reading voltage, charge imbalances are generated along interfaces respectively between the first non-polar layer 802 and the ferroelectric layer 504 and between the second non-polar layer 804 and the ferroelectric layer 504. The charge imbalances will have value dependent upon a remanent polarization of the ferroelectric layer 504. The charge imbalance causes an electric field to form that changes a shape of an energy barrier provided by the ferroelectric layer 504. The change in shape of the energy barrier allows for different read currents to quantum mechanically tunnel through the ferroelectric layer 504. Because the different read currents depend upon the remanent polarization of the ferroelectric layer, the different read currents correspond to a data state stored in the ferroelectric layer 504. By having different read currents generated based upon a data state stored in the ferroelectric layer 504, a data state stored in the ferroelectric layer 504 can be read in a non-destructive manner. Since the read operation is non-destructive, the memory structure has good endurance, good data retention, and low power.

In some embodiments, the first non-polar layer 802 and the second non-polar layer 804 respectively have a thickness T3 ranging from approximately 0.1 nanometers to approximately 2 nanometers, from approximately 0.1 nanometers to approximately 1 nanometer, from approximately 1 nanometer to approximately 2 nanometers, or some other suitable value. In some embodiments, if the thickness T3 is too large (e.g., more than approximately 2 nanometers), the read current may be unable to sufficiently pass through the memory structure, negatively affecting the effectiveness of read operations. In some embodiments, if the thickness T3 is too small (e.g., less than approximately 0.1 nanometers), the first non-polar layer 802 and the second non-polar layer 804 will not provide for a sufficient energy barrier that enables a non-zero net charge at interfaces respectively between the first non-polar layer 802 and the ferroelectric layer 504 and between the second non-polar layer 804 and the ferroelectric layer 504. Without the non-zero net charge at the interfaces, the memory structure may be unable to output different levels of read currents, and hence the memory structure may be unable to output stored data states. In some embodiments, the first non-polar layer 802 and the second non-polar layer 804 have a same thickness. In some embodiments, the first non-polar layer 802 and the second non-polar layer 804 have different thicknesses.

In some embodiments, the first non-polar layer 802 and the second non-polar layer 804 may be or otherwise comprise, for example, silicon dioxide, aluminum oxide, tantalum oxide, or some other suitable non-polar material(s). In some embodiments, the first non-polar layer 802 and the second non-polar layer 704 may have a dielectric constant greater than approximately 8. In some embodiments, the first non-polar layer 802 and the second non-polar layer 804 are or comprise a same material. In some embodiments, the first non-polar layer 802 and the second non-polar layer 804 are or comprise different materials.

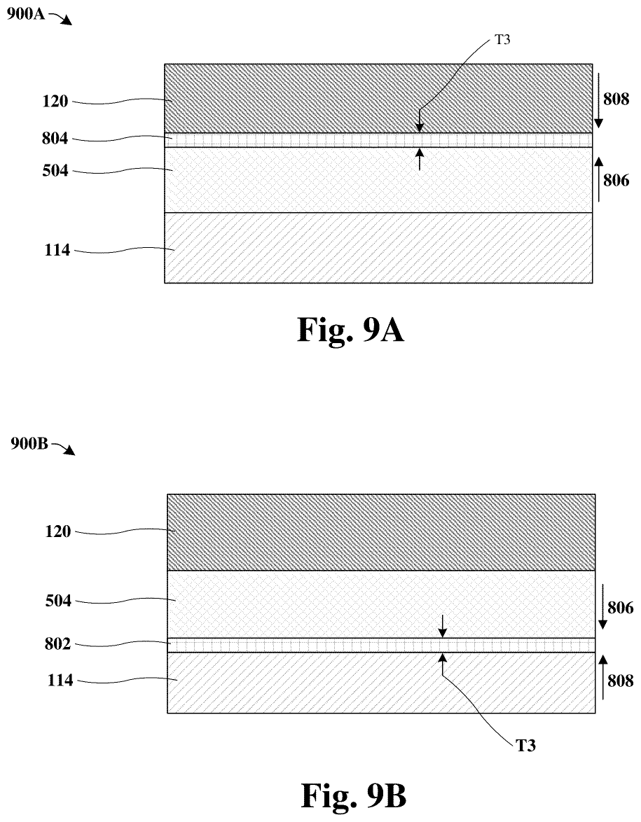

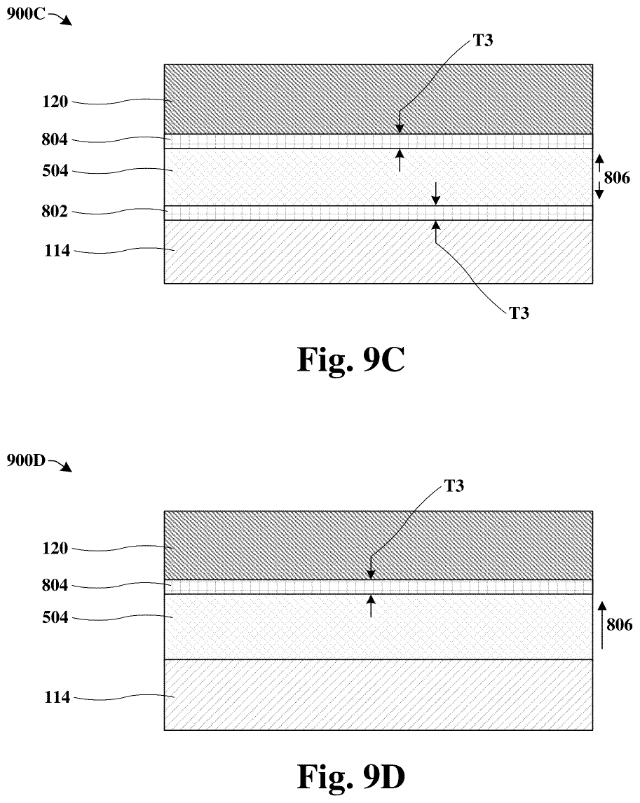

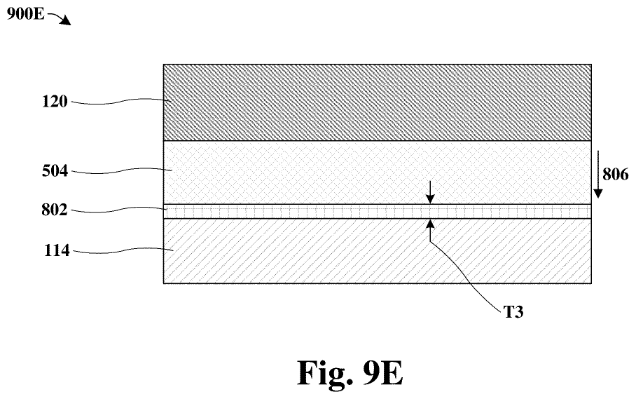

FIGS. 9A-9E illustrate cross-sectional views 900A-900E of some alternative embodiments of the integrated chip of FIG. 8 in which the memory structure is varied.

With respect to cross-sectional view 900A of FIG. 9A, the memory structure is as described with respect to FIG. 8, except the first non-polar layer 802 is omitted. Further, the non-uniform oxygen distribution 806 of the ferroelectric layer 504 is such that the oxygen concentration increases from the bottommost surface of the ferroelectric layer 504 to the topmost surface of the ferroelectric layer 504. In some embodiments, the bottom electrode 114 has a uniform distribution of nitrogen or alternatively has a higher distribution of nitrogen near the ferroelectric layer 504 than the lower region of the bottom electrode 114.

With respect to cross-sectional view 900B of FIG. 9B, the memory structure is as described with respect to FIG. 8, except the second non-polar layer 804 is omitted. Further, the non-uniform oxygen distribution 806 of the ferroelectric layer 504 is such that the oxygen concentration increases from the topmost surface of the ferroelectric layer 504 to the bottommost surface of the ferroelectric layer 504. In some embodiments, the top electrode 120 has a uniform distribution of nitrogen or alternatively has a higher distribution of nitrogen near the ferroelectric layer 504 than the upper region of the top electrode 120.

With respect to cross-sectional view 900C of FIG. 9C, the memory structure is as described with respect to FIG. 8, except the bottom electrode 114 and the top electrode 120 have a uniform nitrogen distribution. In some embodiments, the top electrode 120 and the bottom electrode 114 may have an atomic percent of nitrogen ranging from approximately 10% to approximately 20%, approximately 10% to approximately 15%, approximately 15% to approximately 20%, or some other suitable value. In some embodiments, during fabrication, a thermal process (e.g., a BEOL thermal treatment) may cause the bottom electrode 114 and the top electrode 120 to scavenge oxygen from the ferroelectric layer 504, respectively leading to the formation of the first non-polar layer 802 and the second non-polar layer 804. In some embodiments, the uniform nitrogen distribution of the bottom electrode 114 and the top electrode 120 may cause the bottom electrode 114 and the top electrode 120 to scavenge more oxygen from the ferroelectric layer 504 than an alternative non-uniform nitrogen distribution would, leading to the presence of more oxygen vacancies in the ferroelectric layer 504, hence increasing remanent polarization.

In some embodiments, the uniform nitrogen distribution of the bottom electrode 114 and the top electrode 120 may cause the bottom electrode 114 and the top electrode 120 to fully oxidize. During operation, voltage may drop across the fully oxidized bottom electrode 114 and top electrode 120, increasing operation voltage of the device as compared to the memory structure of FIG. 4. However, the uniform nitrogen distribution of the top electrode 120 and the bottom electrode 114 is cheaper than the non-uniform nitrogen distribution 808 as described in FIG. 8.

With respect to cross-sectional view 900D of FIG. 9D, the memory structure is as described with respect to FIG. 9C, except the first non-polar layer 802 is omitted. Further, the non-uniform oxygen distribution 806 of the ferroelectric layer 504 is such that the oxygen concentration increases from the bottommost surface of the ferroelectric layer 504 to the topmost surface of the ferroelectric layer 504.

With respect to cross-sectional view 900E of FIG. 9E, the memory structure is as described with respect to FIG. 9C, except the second non-polar layer 804 is omitted. Further, the non-uniform oxygen distribution 806 of the ferroelectric layer 504 is such that the oxygen concentration increases from the topmost surface of the ferroelectric layer 504 to the bottommost surface of the ferroelectric layer 504.

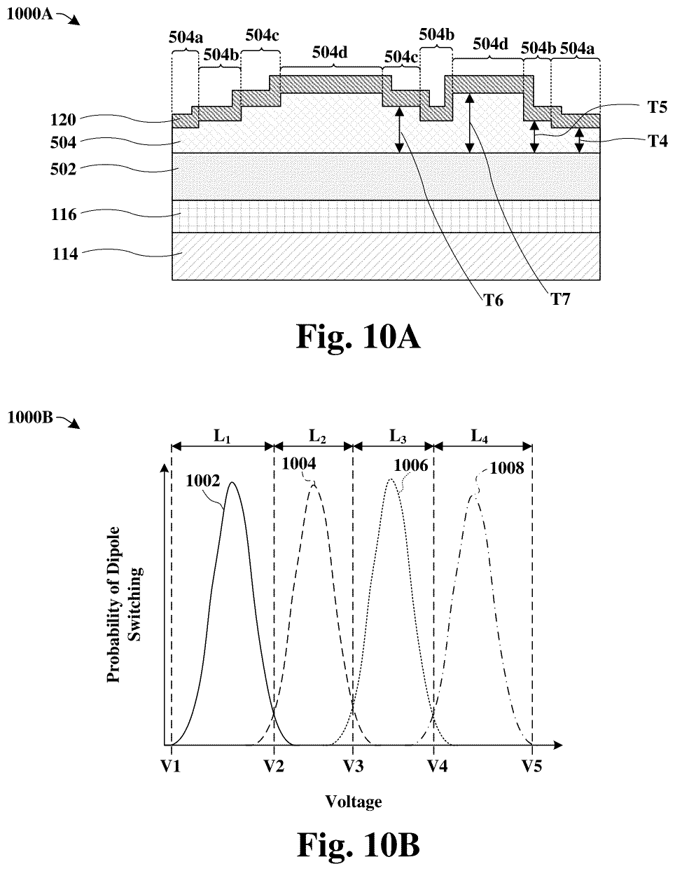

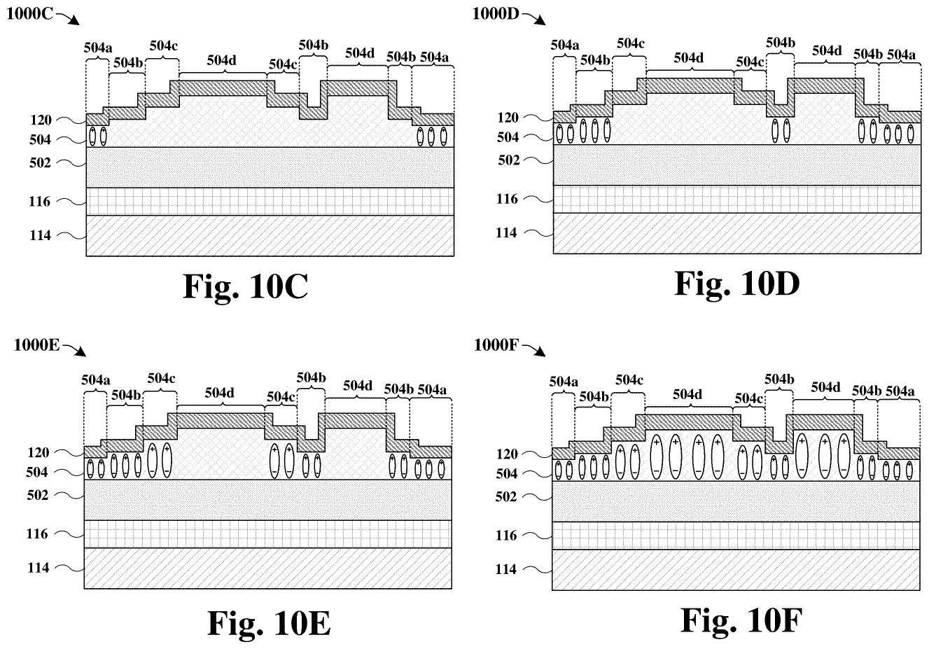

FIG. 10A illustrates a cross-sectional view 1000A of some alternative embodiments of the integrated chip of FIG. 5A in which the ferroelectric layer 504 has a varying thickness as measured between a lower surface of the ferroelectric layer 504 and a lower surface of the top electrode 120 throughout a width of the ferroelectric layer 504. In some embodiments, the ferroelectric layer 504 has a step structure such that top surfaces of the ferroelectric layer 504 are connected to one another by vertical sidewalls of the ferroelectric layer 504. In some embodiments, the top electrode 120 is conformally disposed over the ferroelectric layer 504.

In some embodiments, the ferroelectric layer 504 has a first thickness T4, a second thickness T5 greater than the first thickness T4, a third thickness T6 greater than the second thickness T5, and a fourth thickness T7 greater than the third thickness T6. In some embodiments, areas of the ferroelectric layer 504 having the different thicknesses may correspond to different ferroelectric domains 504a-504d. For example, areas of the ferroelectric layer 504 having a first thickness T4 correspond to a first ferroelectric domain 504a, areas of the ferroelectric layer 504 having a second thickness T5 correspond to a second ferroelectric domain 504b, etc. Dipoles within the different ferroelectric domains 504a-504d are configured to switch at different coercive voltages, so that an overall dipole of the ferroelectric layer 504 can be easily controlled to have different values that will provide for different read currents corresponding to different memory levels.

In some embodiments, the second thickness T5 may be greater than the first thickness T4 by a range of approximately 0.3 nanometers to approximately 0.7 nanometers, approximately 0.5 nanometers to approximately 0.7 nanometers, approximately 0.3 nanometers to approximately 0.5 nanometers, or some other suitable value. In some embodiments, the third thickness T6 may be greater than the second thickness T5 by a range of approximately 0.3 nanometers to approximately 0.7 nanometers, approximately 0.5 nanometers to approximately 0.7 nanometers, approximately 0.3 nanometers to approximately 0.5 nanometers, or some other suitable value. In some embodiments, the fourth thickness T7 may be greater than the third thickness T6 by a range of approximately 0.3 nanometers to approximately 0.7 nanometers, approximately 0.5 nanometers to approximately 0.7 nanometers, approximately 0.3 nanometers to approximately 0.5 nanometers, or some other suitable value.

In alternative embodiments, the ferroelectric layer 504 may have fewer than four different thicknesses. In other alternative embodiments, the ferroelectric layer 504 may have more than four different thicknesses. In alternative embodiments, the memory structure may be as described with respect to FIGS. 7A-7B, FIG. 8, or FIGS. 9A-9E, except that the ferroelectric layer 504 has a varying thickness throughout a width of the ferroelectric layer 504.

FIG. 10B illustrates a graphical representation 1000B of the dipole-switching distribution of the integrated chip of FIG. 10A. Curve 1002 corresponds to a first memory level L₁ of the memory structure. Curve 1004 corresponds to a second memory level L₂. Curve 1006 corresponds to a third memory level L₃. Curve 1008 corresponds to a fourth memory level L₄.

During operation of the memory structure, a memory level corresponding to a plurality of bits of data is stored in the ferroelectric layer 504 using the remanent polarization of the ferroelectric layer 504. In some embodiments, a plurality of ferroelectric domains 504a-504d of the ferroelectric layer 504 may have different remanent polarizations, such that the remanent polarizations of respective ferroelectric domains 504a-504d represent different memory levels.

To program a first memory level L₁, a set voltage or a reset voltage within the first range of between V1 and V2 is applied across the memory structure to switch the dipole of a first ferroelectric domain 504a of the ferroelectric layer 504, setting the remanent polarization of the first ferroelectric domain 504a respectively to the first memory level L₁ (e.g., ‘00’). To program a second memory level L₂, a set voltage or a reset voltage within the second range of between V2 and V3 is applied across the memory structure to switch the dipole of a second ferroelectric domain 504b of the ferroelectric layer 504, setting the remanent polarization of the second ferroelectric domain 504b respectively to the second memory level L₂ (e.g., ‘01’). To program a third memory level L₃, a set voltage or a reset voltage within the third range of between V3 and V4 is applied across the memory structure to switch the dipole of a third ferroelectric domain 504c of the ferroelectric layer 504, setting the remanent polarization of the third ferroelectric domain 504c to the third memory level L₃ (e.g., ‘10’). To program a fourth memory level L₄, a set voltage or a reset voltage that is greater than V4 is applied across the memory structure to switch the dipole of a fourth ferroelectric domain 504d of the ferroelectric layer 504, setting the remanent polarization of the fourth ferroelectric domain 504d to the fourth memory level L₄ (e.g., ‘11’).

To read, a reading voltage less in magnitude than the discrete coercive voltages (e.g., less than voltage V1) is applied across the memory structure, causing a read current to pulse across the memory structure. The read current has a value that is dependent on the polarization of the ferroelectric layer 504 and can therefore be used to detect a memory level stored by the memory structure. Since the reading voltage is less than a dipole-switching voltage of the memory structure, data states are not switched during and/or after the read operation. Since the read operation is non-destructive, the memory structure has better endurance, better retention, and lower power operation.

FIGS. 10C-10F illustrate cross-sectional views 1000C-1000F corresponding to the different memory levels of FIG. 10B. As shown in cross-sectional view 1000C of FIG. 10C, when a set voltage or a reset voltage within the first range is applied across the ferroelectric layer 504, dipoles within a first ferroelectric domain 504a may align to form a remanent polarization having a first strength. As shown in cross-sectional view 1000D of FIG. 10D, when a set voltage or a reset voltage within the second range is applied across the ferroelectric layer 504, dipoles within a first ferroelectric domain 504a and the second ferroelectric domain 504b may align to form a remanent polarization having a second strength. As shown in cross-sectional view 1000E of FIG. 10E, when a set voltage or a reset voltage within the third range is applied across the ferroelectric layer 504, dipoles within a first ferroelectric domain 504a, the second ferroelectric domain 504b, and the third ferroelectric domain 504c may align to form a remanent polarization having a third strength. As shown in cross-sectional view 1000F of FIG. 10F, when a set voltage or a reset voltage of greater than V4 is applied across the ferroelectric layer 504, dipoles within a first ferroelectric domain 504a, the second ferroelectric domain 504b, the third ferroelectric domain 504c, and the fourth ferroelectric domain 504d may align to form a remanent polarization having a fourth strength.

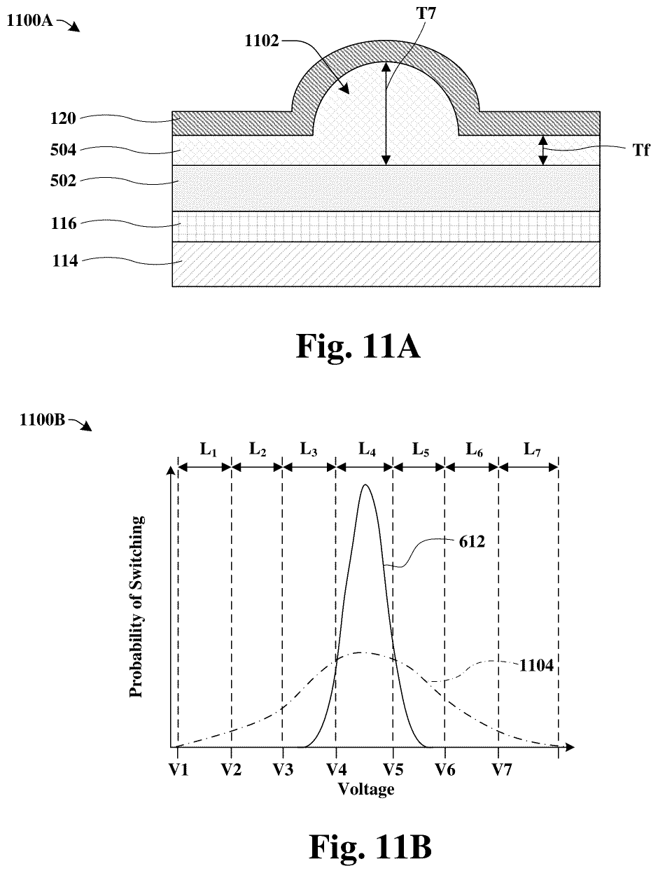

FIG. 11A illustrates a cross-sectional view 1100A of some alternative embodiments of the integrated chip of FIG. 5A in which the ferroelectric layer 504 has a protrusion portion 1102 extending from a central portion of the ferroelectric layer 504 and towards the top electrode 120. In some embodiments, the protrusion portion 1102 has a semicircle profile. In some embodiments, the top electrode 120 is conformally disposed over the ferroelectric layer 504. The ferroelectric layer 504 has fewer sharp edges than the ferroelectric layer 504 of FIG. 10A. Since extensive stress to sharp edges can degrade ferroelectric film quality during operation of the memory structure, the protrusion portion 1102 improves endurance of the memory structure as compared to that of FIG. 10A. In alternative embodiments, the memory structure may comprise a plurality of protrusion portions similar to the protrusion portion 1102. In some embodiments, the ferroelectric layer 504 has a thickness T7 as measured from a bottommost surface of the ferroelectric layer 504 to a topmost point of the protrusion portion 1102. In some embodiments, the thickness T7 may range from approximately 4.5 nanometers to approximately 10 nanometers, approximately 4.5 nanometers to approximately 7.5 nanometers, approximately 7.5 nanometers to approximately 10 nanometers, or some other suitable value. In alternative embodiments, the memory structure may be as described with respect to FIGS. 7A-7B, FIG. 8, or FIGS. 9A-9E, except that the ferroelectric layer 504 comprises a protrusion portion 1102.

FIG. 11B illustrates a graphical representation 1100B of the dipole-switching distribution of the integrated chip of FIG. 11A. Curve 1104 corresponds to a plurality of ranges of coercive voltages of the integrated chip of FIG. 11A and curve 612 corresponds to a plurality of ranges of coercive voltages of the memory structure 602 of FIG. 6A. Since the curve 1104 is wider than the curve 612, more memory levels can be stored in the ferroelectric layer 504 of FIG. 11A than in the ferroelectric layer 504 of FIG. 6A. Further, respective ranges of the plurality of ranges of coercive voltages corresponding to curve 1104 are larger than those corresponding to curve 612. Hence, programming voltages do not require as much precision, improving performance.

During operation of the memory structure, a memory level corresponding to a plurality of bits of data is stored in the ferroelectric layer 504 using the remanent polarization of the ferroelectric layer 504. In some embodiments, a plurality of ferroelectric domains of the ferroelectric layer 504 may have different remanent polarizations, such that the remanent polarizations of respective ferroelectric domains represent different memory levels.

To program a first memory level L₁, a set voltage or a reset voltage within the first range of between V1 and V2 is applied across the memory structure to switch the dipole of a first ferroelectric domain of the ferroelectric layer 504, setting the remanent polarization of the first ferroelectric domain respectively to the first memory level L₁ (e.g., ‘000’). To program a second memory level L₂, a set voltage or a reset voltage within the second range of between V2 and V3 is applied across the memory structure to switch the dipole of a second ferroelectric domain of the ferroelectric layer 504, setting the remanent polarization of the second ferroelectric domain respectively to the second memory level L₂ (e.g., ‘001’). To program a third memory level L₃, a set voltage or a reset voltage within the third range of between V3 and V4 is applied across the memory structure to switch the dipole of a third ferroelectric domain of the ferroelectric layer 504, setting the remanent polarization of the third ferroelectric domain to the third memory level L₃ (e.g., ‘010’). To program a fourth memory level L₄, a set voltage or a reset voltage within the fourth range of between V4 and V5 is applied across the memory structure to switch the dipole of a fourth ferroelectric domain of the ferroelectric layer 504, setting the remanent polarization of the fourth ferroelectric domain to the fourth memory level L₄ (e.g., ‘011’). To program a fifth memory level L₅, a set voltage or a reset voltage within the fifth range of between V5 and V6 is applied across the memory structure to switch the dipole of a fifth ferroelectric domain of the ferroelectric layer 504, setting the remanent polarization of the fifth ferroelectric domain respectively to the fifth memory level L₅ (e.g., ‘100’). To program a sixth memory level L₆, a set voltage or a reset voltage within the sixth range of between V6 and V7 is applied across the memory structure to switch the dipole of a sixth ferroelectric domain of the ferroelectric layer 504, setting the remanent polarization of the sixth ferroelectric domain respectively to the sixth memory level L₆ (e.g., ‘101’). To program a seventh memory level L₇, a set voltage or a reset voltage within the seventh range of between V7 and V8 is applied across the memory structure to switch the dipole of a seventh ferroelectric domain of the ferroelectric layer 504, setting the remanent polarization of the seventh ferroelectric domain to the third memory level L₇ (e.g., ‘110’). To program an eighth memory level L₈, a set voltage or a reset voltage that is greater than V8 is applied across the memory structure to switch the dipole of an eighth ferroelectric domain of the ferroelectric layer 504, setting the remanent polarization of the eighth ferroelectric domain to the eighth memory level L₄ (e.g., ‘111’).

To read, a reading voltage less in magnitude than the discrete coercive voltages (e.g., less than voltage V1) is applied across the memory structure, causing a read current to pulse across the memory structure. The read current has a value that is dependent on the polarization of the ferroelectric layer 504 and can therefore be used to detect a memory level stored by the memory structure. Since the reading voltage is less than a dipole-switching voltage of the memory structure, data states are not switched during and/or after the read operation. Since the read operation is non-destructive, the memory structure has better endurance, better retention, and lower power operation.

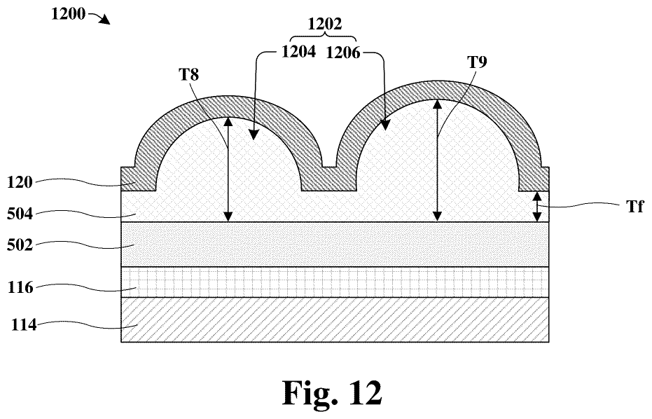

FIG. 12 illustrates a cross-sectional view 1200 of some alternative embodiments of the integrated chip of FIG. 11A in which the ferroelectric layer comprises a plurality of protrusion portions 1202 having different thicknesses. The plurality of protrusion portions 1202 comprise a first protrusion portion 1204 and a second protrusion portion 1206. In some embodiments, the first protrusion portion 1204 may be as described with respect to the protrusion portion 1102 of FIG. 11A. The first protrusion portion 1204 has a first thickness T8 and the second protrusion portion 1206 has a second thickness T9. In some embodiments, the first thickness T8 may be as described with respect to the thickness T7 of FIG. 11A. In some embodiments, the second thickness T9 may be greater than the first thickness T8.

In some embodiments, the first protrusion portion 1204 may correspond to a first ferroelectric domain, and the second protrusion portion 1206 may correspond to a second ferroelectric domain. In some embodiments, since the ferroelectric layer 504 comprises a plurality of protrusion portions 1202, each of the memory levels stored in the ferroelectric layer 504 of FIG. 12 can have a larger voltage range thereby more clearly defining the different memory levels. In alternative embodiments, the plurality of protrusion portions 1202 may comprise more than two protrusion portions.

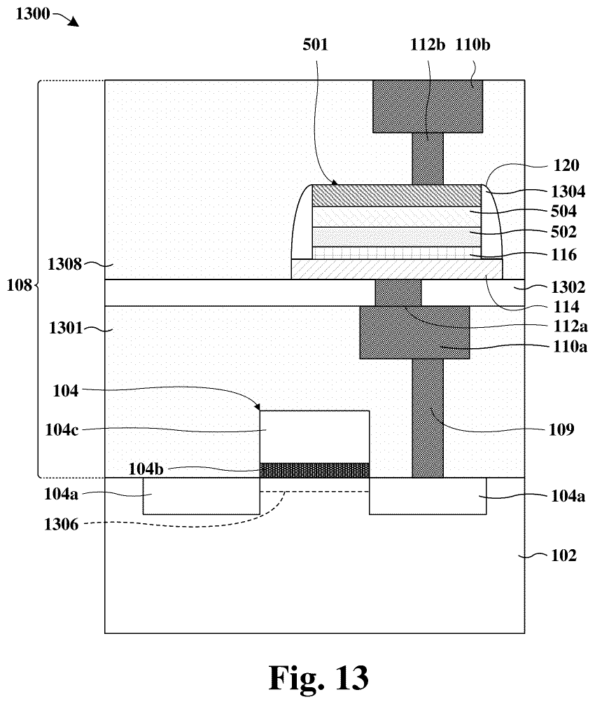

FIG. 13 illustrates a cross-sectional view 1300 of some embodiments of an integrated chip in which a 1T1C memory structure comprises the memory structure 501 having a ferroelectric tunnel junction. In some embodiments, the memory structure 501 is as described with respect to the memory structure 501 of FIG. 5A. In alternative embodiments, the memory structure 501 may be as described with respect to FIGS. 7A-7B, FIG. 8, FIG. 9A-9E, FIG. 10A, FIG. 11A, or FIG. 12. The memory structure 501 overlies and is electrically coupled to a semiconductor device 104. The semiconductor device 104 is on and partially within a substrate 102. Further, the semiconductor device 104 comprises source/drain regions 104a, a gate dielectric layer 104b, and a gate electrode 104c. The source/drain regions 104a are embedded in a top of the substrate 102, and the gate dielectric layer 104b and the gate electrode 104c are stacked laterally between the source/drain regions 104a. In some embodiments, the semiconductor device 104 is a planar field-effect transistor (FET), a fin FET (FinFET), a gate-all-around (GAA) FET, or some other suitable type of semiconductor device.

An interconnect structure overlies the substrate 102 and electrically couples to the memory structure 501 and the semiconductor device 104. In some embodiments, the interconnect structure comprises a network of conductive contacts 109, interconnect wires 110a-110b, and interconnect vias 112a-112b arranged within an interconnect dielectric structure 108. In some embodiments, the interconnect dielectric structure 108 comprises a lower dielectric structure 1301 and an upper dielectric structure 1308 separated by an etch stop layer 1302. In some embodiments, the interconnect vias 112a-112c comprise a first interconnect via 112a and a second interconnect via 112b. In some embodiments, the interconnect wires 110a-110b comprise a first interconnect wire 110a and a second interconnect wire 110b. In some embodiments, the conductive contact 109 extends from the first interconnect wire 110a to one of the source/drain regions 104a, while the second interconnect via 112a extends from the first interconnect wire 110a to the bottom electrode 114. In some embodiments, the first interconnect via 112a is a bottom electrode via (BEVA) and is at a bottom of the memory structure 501. In some alternative embodiments, one or more additional interconnect wires and/or interconnect vias may be disposed between the source/drain regions 104a and the memory structure 501.

The etch stop layer 1302 surrounds sidewalls of the first interconnect via 112a. Sidewall spacers 1304 surround opposing sidewalls of the memory structure 501. The second interconnect via 112b overlies the memory structure 501 and extends from the second interconnect wire 110b to the memory structure 501. In some embodiments, the second interconnect via 112b electrically couples the top electrode 120 to the second interconnect wire 110b.

During operation, the gate electrode 104c is biased so a channel region 1306 conducts and electrically connects the source/drain regions 104a. A reading voltage is then applied across the memory structure 501 through the channel region 1306 of the semiconductor device 104, and the non-polar layer 116 may screen charges from the reading voltage. By screening charges from the reading voltage, a charge imbalance is generated along an interface between the intermediate electrode 502 and the ferroelectric layer 504. The charge imbalance will have a value that is dependent upon a remanent polarization of the ferroelectric layer 504. The charge imbalance causes an electric field to form that changes a shape of an energy barrier provided by the ferroelectric layer 504. The change in shape of the energy barrier allows for different read currents to quantum mechanically tunnel through the ferroelectric layer 504. Because the different read currents depend upon the remanent polarization of the ferroelectric layer, the different read currents correspond to a data state stored in the ferroelectric layer 504. By having different read currents generated based upon a data state stored in the ferroelectric layer 504, a data state stored in the ferroelectric layer 504 can be read in a non-destructive manner. Since the read operation is non-destructive, the memory structure 501 has good endurance, good data retention, and low power.

For example, to program a first memory level L₁ within the ferroelectric layer 504, the gate electrode 104c is biased so the channel region 1306 conducts and electrically connects the source/drain regions 104a. A first set voltage or a reset voltage is applied across the memory structure 501 through the channel region 1306 of the semiconductor device 104 to switch the dipole of a first ferroelectric domain of the ferroelectric layer 504, setting the remanent polarization of the ferroelectric layer 504 to a first value corresponding to a first memory level L₁. In some embodiments, the first memory level L₁ may correspond to a first pair of data states (e.g., ‘00’). To program a second memory level L₂ within the ferroelectric layer 504, the gate electrode 104c is biased so the channel region 1306 conducts and electrically connects the source/drain regions 104a. A second set voltage or a reset voltage greater than the first set voltage or a reset voltage is applied across the memory structure 501 through the channel region 1306 of the semiconductor device 104 to switch the dipole of a second ferroelectric domain of the ferroelectric layer 504, setting the remanent polarization of the ferroelectric layer 504 to a second value corresponding to a second memory level L₂. In some embodiments, the second memory level L₂ may correspond to a second pair of data states (e.g., ‘01’). To program a third memory level L₃ within the ferroelectric layer 504, the gate electrode 104c is biased so the channel region 1306 conducts and electrically connects the source/drain regions 104a. A third set voltage or a reset voltage greater than the second set voltage or a reset voltage is applied across the memory structure 501 through the channel region 1306 of the semiconductor device 104 to switch the dipole of a third ferroelectric domain of the ferroelectric layer 504, setting the remanent polarization of the ferroelectric layer 504 to a third value that corresponds to a third memory level L₃. In some embodiments, the third memory level L₃ may correspond to a third pair of data states (e.g., ‘10’). To program a fourth memory level L₄ within the ferroelectric layer 504, the gate electrode 104c is biased so the channel region 1306 conducts and electrically connects the source/drain regions 104a. A fourth set voltage or a reset voltage greater than the third set voltage or a reset voltage is applied across the memory structure 501 through the channel region 1306 of the semiconductor device 104 to switch the dipole of a fourth ferroelectric domain (e.g., 504d) of the ferroelectric layer 504, setting the remanent polarization of the ferroelectric layer 504 to a fourth memory level L₄. In some embodiments, the fourth memory level L₄ may correspond to a fourth pair of data states (e.g., ‘11’).

In some embodiments, the substrate 102 is a bulk substrate of silicon, a silicon-on-insulator (SOI) substrate, or some other suitable semiconductor substrate. In some embodiments, the source/drain regions 104a are doped regions of the substrate 102. In other embodiments, the source/drain regions 104a are independent of the substrate 102 and overlie a top surface of the substrate 102. In some embodiments, the gate electrode 104c is or comprises doped polysilicon, metal, some other suitable conductive material, or any combination of the foregoing. In some embodiments, the gate dielectric layer 104b is or comprises silicon dioxide and/or some other suitable dielectric material(s). In some embodiments, the conductive contacts 109, the interconnect wires 110a-110b and the interconnect vias 112a-112b are or comprise metal and/or some other suitable conductive material. In some embodiments, the interconnect dielectric structure 108 is or comprises an oxide and/or some other suitable dielectric material(s). In some embodiments, the etch stop layer 1302 may be or comprise, for example, silicon carbide (e.g., SiC), silicon nitride (e.g., SiN), some other suitable dielectric(s), or any combination of the foregoing. In some embodiments, the sidewall spacers 1304 may, for example, be or comprise titanium nitride, silicon oxide, silicon nitride, silicon carbide nitride, silicon oxide nitride, metal oxide, some other suitable material(s), or any combination of the foregoing.

While the memory structure 501 is illustrated as described with respect to the memory structure 501 of FIG. 5A, the memory structure 501 may be as described with respect to any one of the memory structures of FIGS. 7A-7B, FIG. 8, FIGS. 9A-9E, FIG. 10A, FIG. 11A, or FIG. 12. While the memory structure 501 is described as part of a 1T1C memory structure, the memory structure 501 may alternatively be part of a two-transistor two-capacitor (2T2C) memory structure in alternative embodiments.

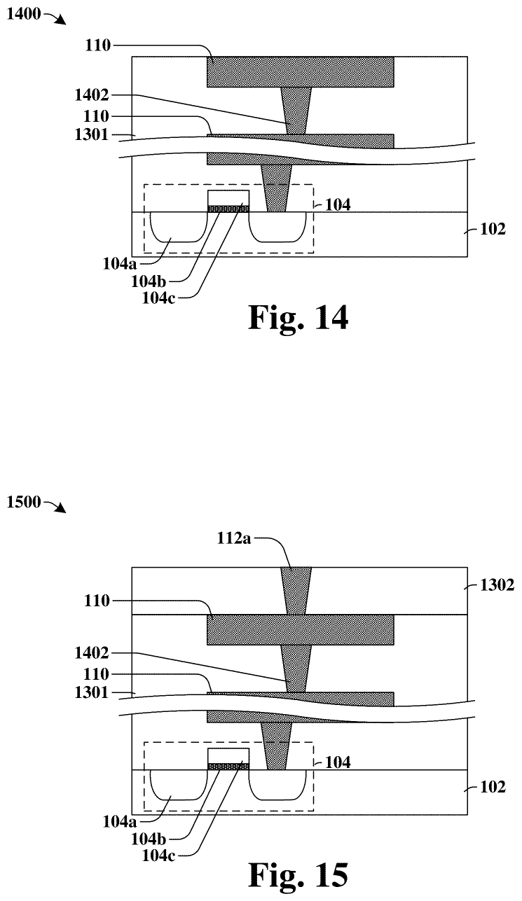

FIGS. 14-19 illustrate cross-sectional views 1400-1900 of some embodiments of a method of forming an integrated chip having an ATJ structure that comprises a non-polar layer and an anti-ferroelectric layer. Although FIGS. 14-19 are described in relation to a method, it will be appreciated that the structures disclosed in FIGS. 14-19 are not limited to such a method, but instead may stand alone as structures independent of the method.

As shown in cross-sectional view 1400 of FIG. 14, a substrate 102 is provided. In various embodiments, the substrate 102 may comprise any type of semiconductor body (e.g., silicon/CMOS bulk, SiGe, SOI, etc.) such as a semiconductor wafer or one or more die on a wafer, as well as any other type of semiconductor and/or epitaxial layers formed thereon and/or otherwise associated therewith. A semiconductor device 104 may be formed over the substrate 102 and may comprise source/drain regions 104a, a gate electrode 104c, and a gate dielectric layer 104b. A lower dielectric structure 1301 is formed over the substrate 102. In some embodiments, the lower dielectric structure 1301 comprises one or more interconnect dielectric layers formed by a deposition process (e.g., physical vapor deposition (PVD), chemical vapor deposition (CVD), atomic layer deposition (ALD), etc.). In some embodiments, the one or more interconnect dielectric layers of the lower dielectric structure 1301 comprise for example, a nitride (e.g., silicon nitride, silicon oxynitride), a carbide (e.g., silicon carbide), an oxide (e.g., silicon oxide), borosilicate glass (BSG), phosphoric silicate glass (PSG), borophosphosilicate glass (BPSG), a low-k oxide (e.g., a carbon doped oxide, SiCOH), or some other suitable dielectric material.

In some embodiments, interconnect wires 110 and additional interconnect vias 1402 are formed within the lower dielectric structure 1301. In some embodiments, the interconnect wires 110 and the additional interconnect vias 1402 are formed by way of various steps of photolithography, removal (e.g., etching, chemical mechanical planarization (CMP)), and deposition (e.g., PVD, CVD, ALD, sputtering, etc.) processes. For example, in some embodiments, the interconnect wires 110 and the additional interconnect vias 1402 may be formed within the lower dielectric structure 1301 using a damascene process (e.g., a single damascene process or a dual damascene process). In some embodiments, the interconnect wires 110 and the additional interconnect vias 1402 may comprise tungsten, copper, and/or aluminum, and/or the like.

As shown in cross-sectional view 1500 of FIG. 15, in some embodiments, an etch stop layer 1302 is formed over the lower dielectric structure 1301 and one of the interconnect wires 110. The etch stop layer 1302, in some embodiments, may comprise a different material than the lower dielectric structure 1301. In other embodiments, the etch stop layer 1302 may comprise the same material as the lower dielectric structure 1301. The etch stop layer 1302 may, for example, comprise an oxide (e.g., silicon rich oxide), a nitride (e.g., silicon nitride, silicon oxynitride), a carbide (e.g., silicon carbide), or the like. In some embodiments, the etch stop layer 1302 may be deposited by a deposition process (e.g., PVD, CVD, PE-CVD, ALD, etc.). Further, in some embodiments, a first interconnect via 112a is formed within the etch stop layer 1302 to contact one of the interconnect wires 110. In some embodiments, the first interconnect via 112a is formed within the etch stop layer 1302 through various steps of photolithography, removal (e.g., etching, chemical mechanical planarization (CMP)), and deposition (e.g., PVD, CVD, ALD, sputtering, etc.) processes.

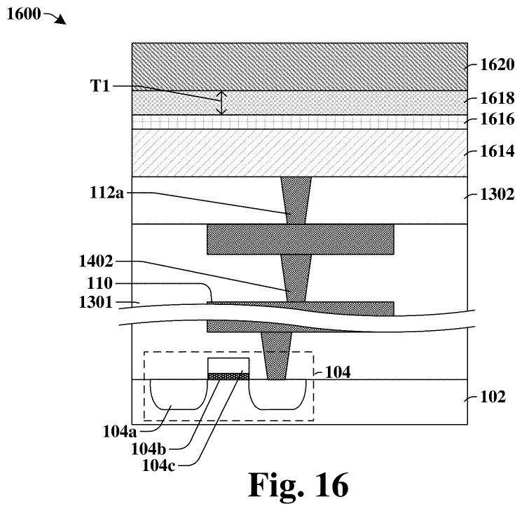

As shown in cross-sectional view 1600 of FIG. 16, a first electrode layer 1614 is formed over the etch stop layer 1302 and on the first interconnect via 112a. In some embodiments, the first electrode layer 1614 comprises a first material that has a first work function. In some embodiments, the first electrode layer 1614 comprises, for example, tantalum nitride titanium nitride, platinum, ruthenium, indium tin oxide, indium gallium zinc oxide, or some other suitable conductive material. In some embodiments, the first electrode layer 1614 is formed by way of a deposition process (e.g., PVD, CVD, ALD, sputtering, etc.). In some embodiments, the first electrode layer 1614 has a thickness in a range of between, for example, approximately 10 nanometers and approximately 100 nanometers.

In some embodiments, a conformal non-polar layer 1616 is formed over the first electrode layer 1614. In some embodiments, the conformal non-polar layer 1616 comprises a non-polar material that has a dielectric constant that is greater than about 8. For example, in some embodiments, the conformal non-polar layer 1616 comprises, for example, aluminum oxide, silicon dioxide, tantalum oxide, or some other suitable dielectric layer. In some embodiments, the conformal non-polar layer 1616 is formed by way of a deposition process (e.g., PVD, CVD, ALD, sputtering, etc.). In some embodiments, the conformal non-polar layer 1616 has a thickness in a range of between, for example, approximately 0.1 nanometers and approximately 2 nanometers. The conformal non-polar layer 1616 has a dielectric constant that is greater than about 8 such that the thickness of the conformal non-polar layer 1616 can be small enough (e.g., less than about 2 nanometers) while also reliable.

In some embodiments, a conformal anti-ferroelectric layer 1618 is formed over the conformal non-polar layer 1616. In some embodiments, the conformal anti-ferroelectric layer 1618 is formed by way of a deposition process (e.g., PVD, CVD, ALD, sputtering, etc.). In some embodiments, the conformal anti-ferroelectric layer 1618 comprises an anti-ferroelectric material that can be crystallized at a temperature less than an annealing temperature of the interconnect structure 106 and that can have anti-ferroelectric properties at a small thickness. In some embodiments, for example, the conformal anti-ferroelectric layer 1618 is formed to have a first thickness T1 in a range of between approximately 0.1 nanometers and approximately 5 nanometers. If the first thickness T1 were greater than 5 nanometers, then the detectability of the crystal structure through current sensing would be indistinguishable; therefore, if the first thickness T1 were greater than 5 nanometers, the conformal anti-ferroelectric layer 1618 would be unreliable for memory storage applications. In some embodiments, the conformal anti-ferroelectric layer 1618 has a crystallization temperature in a range of between, for example, approximately 50 degrees Celsius and approximately 400 degrees Celsius. The conformal anti-ferroelectric layer 1618 is crystallized during the formation of the conformal anti-ferroelectric layer 1618 such that the conformal anti-ferroelectric layer 1618 has a crystal structure that is crystalline and that is configured to switch between two crystal structure phases upon sufficient writing voltages applied across the conformal anti-ferroelectric layer 1618. If the crystallization temperature of the conformal anti-ferroelectric layer 1618 was greater than 400 degrees Celsius, then the formation of the conformal anti-ferroelectric layer 1618 would damage the underlying interconnect structure 106 because of metal diffusion, delamination, or some other thermal damage. In some embodiments, the conformal anti-ferroelectric layer 1618 comprises zirconium oxide, lead zirconium oxide, polyvinylidene fluoride, zirconium-rich (e.g., greater than 70 percent zirconium) hafnium zirconium oxide, or some other suitable anti-ferroelectric material.

In some embodiments, a second electrode layer 1620 is formed over conformal anti-ferroelectric layer 1618. In some embodiments, the first electrode layer 1614 comprises a second material that has a second work function. The second material of the second electrode layer 1620 is different than the first material of the first electrode layer 1614 such that the second work function of the second electrode layer 1620 is different than the first work function of the first electrode layer 1614. In some embodiments, the second electrode layer 1620 comprises, for example, tantalum nitride titanium nitride, platinum, ruthenium, indium tin oxide, indium gallium zinc oxide, or some other suitable conductive material. In some embodiments, the second electrode layer 1620 is formed by way of a deposition process (e.g., PVD, CVD, ALD, sputtering, etc.). In some embodiments, the second electrode layer 1620 has a thickness in a range of between, for example, approximately 10 nanometers and approximately 100 nanometers.

In some embodiments, after the formation of the electrode and conformal layers 1614, 1616, 1618, 1620 in FIG. 16, a crystallization process is performed to crystallize the conformal anti-ferroelectric layer 1618. The conformal anti-ferroelectric layer 1618 is crystallized such that the conformal anti-ferroelectric layer 1618 has a crystalline structure that is configured to switch between various crystalline phases upon signals (e.g., current, voltage) applied across the conformal anti-ferroelectric layer 1618 for future data storage operations. The crystallization temperature of the conformal anti-ferroelectric layer 1618 is less than or equal to a maximum annealing temperature used in the method disclosed in the cross-sectional views 1400-1900 such that the conformal anti-ferroelectric layer 1618 can be crystallized and formed within an interconnect structure without damaging the interconnect structure.

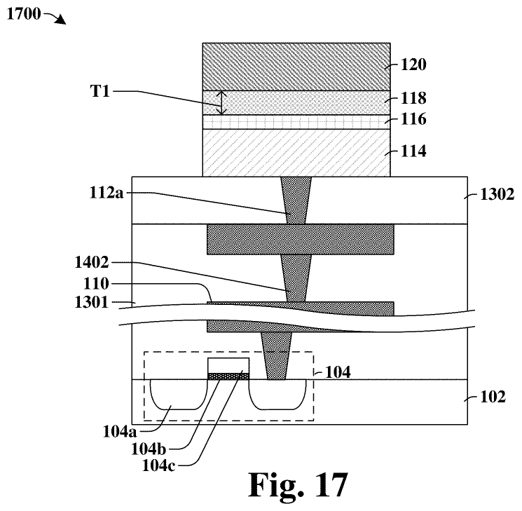

It will be appreciated that in some other embodiments, the conformal anti-ferroelectric layer 1618 is formed on the first electrode layer 1614, and then the conformal non-polar layer 1616 is formed on the conformal anti-ferroelectric layer 1618 to eventually arrive at the ATJ structure 101 illustrated in FIG. 2, for example. Further, it will be appreciated that in some other embodiments, the crystallization process to crystallize the conformal anti-ferroelectric layer 1618 may occur in future processing steps such as, for example, after the steps in either of FIG. 17, 18, or 19.

As shown in cross-sectional view 1700 of FIG. 17, in some embodiments, peripheral portions of the first electrode layer (1614 of FIG. 16), the conformal non-polar layer (1616 of FIG. 16), the conformal anti-ferroelectric layer (1618 of FIG. 16), and the second electrode layer (1620 of FIG. 16) are removed to form a bottom electrode 114, a non-polar layer 116, an anti-ferroelectric layer 118, and a top electrode 120, respectively, over the interconnect structure 106. In some embodiments, the removal process of FIG. 17 comprises a photolithography and etching process. In some embodiments, more than one etchant is used because the various layers (114, 116, 118, 120) comprise different materials. In some other embodiments, a same etchant can remove the materials of each of the layers (114, 116, 118, 120). In some embodiments, the etch stop layer 1302 is substantially resistant to the removal process of FIG. 8 such that the lower dielectric structure 1301, the interconnect wires 110, and the additional interconnect vias 1402 are protected from the removal process of FIG. 17. After the removal process of FIG. 17, an ATJ structure 101 is formed that comprises the bottom electrode 114, the non-polar layer 116, the anti-ferroelectric layer 118, and the top electrode 120 arranged over and coupled to the first interconnect via 112a and the semiconductor device 104.

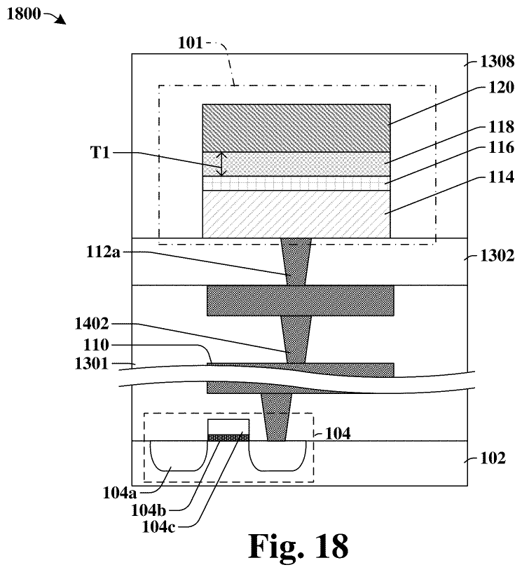

As shown in cross-sectional view 1800 of FIG. 18, in some embodiments, an upper dielectric structure 1308 is formed over and around the ATJ structure 101 to define an interconnect dielectric structure 108. In some embodiments, the upper dielectric structure 1308 is formed similarly to and comprises the same or similar materials as the lower dielectric structure 1301. In some embodiments, the upper dielectric structure 1308 comprises one or more interconnect dielectric layers.

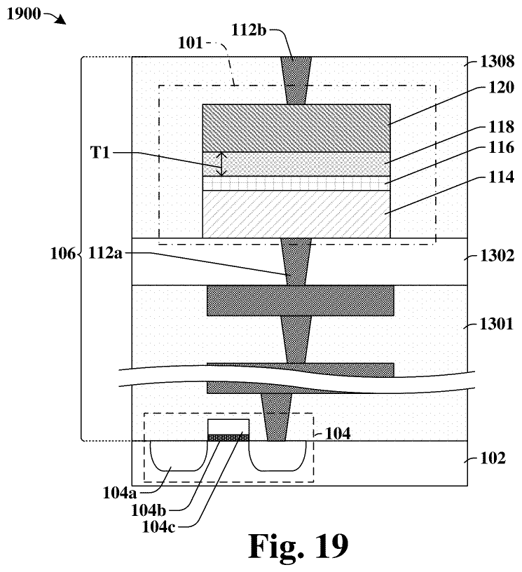

As shown in cross-sectional view 1900 of FIG. 19, in some embodiments, a second interconnect via 112b is formed within the upper dielectric structure 1308 to contact the top electrode 120 and to define an interconnect structure 106. In some embodiments, the second interconnect via 112b is formed by way of a damascene process that uses photolithography, removal (e.g., etching, CMP), and deposition (e.g., PVD, CVD, ALD, sputtering, etc.) processes. In some embodiments, the second interconnect via 112b comprises the same or similar materials as the other interconnect wires 110 and/or the first interconnect via 112.

In some embodiments, the ATJ structure 101 is accessed for memory storage operations by applying a signal (e.g., current, voltage) across the bottom and top electrodes 114, 120 through the interconnect structure 106. In some embodiments, the crystal structure of the anti-ferroelectric layer 118 is changed based on the signal value applied across the ATJ structure 101. In some embodiments, the anti-ferroelectric layer 118 has different resistance values depending on its crystal structure. Thus, data can be read from the anti-ferroelectric layer 118 by determining the resistance of the anti-ferroelectric layer 118 through current sensing across the ATJ structure 101. Because the top electrode 120 has a different work function than the bottom electrode 114, a built-in bias is formed across the anti-ferroelectric layer 118. Further, the non-polar layer 116 contributes to the built-in bias through asymmetrical charge screening effect with dipole moments. Because of the built-in bias, the anti-ferroelectric layer 118 can maintain its crystal structure even when no external signal (e.g., current, voltage) is applied to the ATJ structure 101. Therefore, the ATJ structure 101 does not require constant power to store different data values.

Further, the built-in bias reduces the magnitude of the signal (e.g., current, voltage) needed to switch the data state of the anti-ferroelectric layer 118, which improves the longevity of the ATJ structure 101. Also, the anti-ferroelectric layer 118 is substantially thin (e.g., T1 is less than about 5 nanometers) such that the anti-ferroelectric layer 118 can have a low crystallization temperature (e.g., less than about 400 degrees Celsius) while still having distinguishable resistance values during read operations. Therefore, because the crystallization temperature is low, the anti-ferroelectric layer 118 can be integrated into the interconnect structure 106 without damaging the interconnect structure 106 for use in a variety of applications.

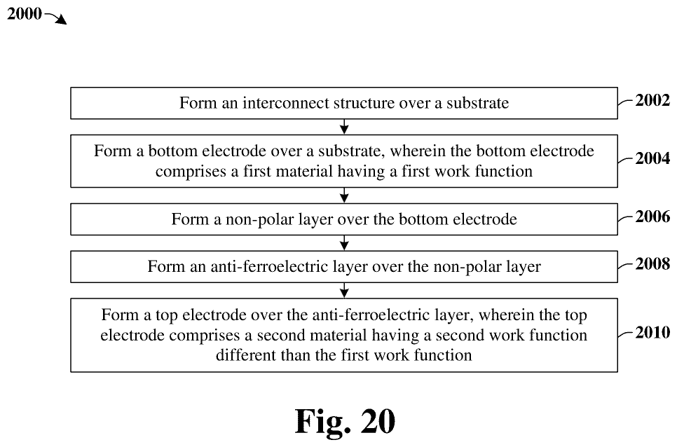

FIG. 20 illustrates a flow diagram of some embodiments of a method 2000 corresponding to the method illustrated in FIGS. 14-19

While method 2000 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 2002 an interconnect structure is formed over a substrate. FIGS. 14 and 15 illustrate cross-sectional views 1400 and 1500 of some embodiments corresponding to act 2002.

At act 2004, a bottom electrode is formed over a substrate, wherein the bottom electrode comprises a first material having a first work function.

At act 2006, a non-polar layer is formed over the bottom electrode.

At act 2008, an anti-ferroelectric layer is formed over the non-polar layer.

At act 2010, a top electrode is formed over the anti-ferroelectric layer. The top electrode comprises a second material having a second work function that is different than the first work function. FIGS. 16 and 17 illustrate cross-sectional views 1600 and 1700 of some embodiments corresponding to acts 2004, 2006, 2008, and 2010.

Therefore, the ATJ structure of the present disclosure comprises an anti-ferroelectric layer and a non-polar layer between two electrodes to improve device longevity, make the ATJ structure non-volatile, and to form an ATJ structure that can be easily integrated into interconnect structures for a variety of applications.

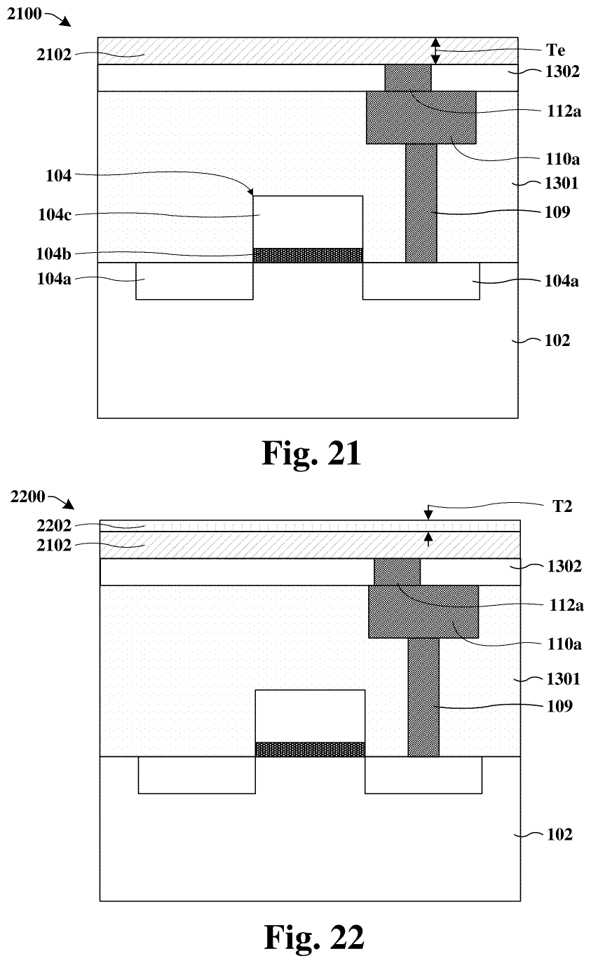

FIGS. 21-29 illustrate a series of cross-sectional views of some embodiments of a method for forming an integrated chip in which a 1T1C memory structure comprises a memory structure 501 having a ferroelectric tunnel junction. Although FIGS. 21-29 are described in relation to a method, it will be appreciated that the structures disclosed in FIGS. 21-29 are not limited to such a method, but instead may stand alone as structures independent of the method.

As illustrated by the cross-sectional view 2100 of FIG. 21, a semiconductor device 104 is formed on a substrate 102. The semiconductor device 104 comprises source/drain regions 104a, a gate dielectric layer 104b, and a gate electrode 104c. A lower dielectric structure 1301 is formed over the semiconductor device 104. Further, a network of conductive contacts 109, a first interconnect wire 110a, and a first interconnect via 112a is formed within the lower dielectric structure 1301. In some embodiments, first interconnect wire 110a is formed to overlie the substrate 102. The conductive contacts 109 are formed to connect one of the source/drain regions 104a to the first interconnect wire 110a. In some embodiments, the first interconnect via 112a is a bottom electrode via (BEVA) and is formed over the first interconnect wire 110a and between sidewalls of an etch stop layer 1302. A first electrode layer 2102 is formed over the first interconnect via 112a. In some embodiments, the first electrode layer 2102 is formed to have a thickness Te ranging from approximately 10 nanometers to approximately 100 nanometers, approximately 10 nanometers to approximately 50 nanometers, approximately 50 nanometers to approximately 100 nanometers, or some other suitable value.

A process for forming the first electrode layer 2102 may be or comprise depositing the first electrode layer 2102 by direct current (DC) sputtering, physical vapor deposition (PVD), chemical vapor deposition (CVD), atomic layer deposition (ALD), some other suitable deposition process, or any combination of the foregoing. In some embodiments, the first electrode layer 2102 is as described with regard to the bottom electrode 114 of FIG. 5A.

As illustrated by the cross-sectional view 2200 of FIG. 22, a first conformal non-polar layer 2202 is formed over the first electrode layer 2102. A process for forming the first conformal non-polar layer 2202 may be or comprise depositing the first conformal non-polar layer 2202 by PVD, CVD, ALD, some other suitable deposition process, or any combination of the foregoing. In some embodiments, the first conformal non-polar layer 2202 is formed to have a thickness T2 ranging from approximately 0.1 nanometers to approximately 1 nanometer, from approximately 0.1 nanometers to approximately 0.5 nanometers, from approximately 0.5 nanometers to approximately 1 nanometer, or some other suitable value. In some embodiments, if the thickness T2 is too large (e.g., more than approximately 1 nanometer), read current may be unable to sufficiently pass through the memory structure, negatively affecting the effectiveness of read operations. In some embodiments, if the thickness T2 is too small (e.g., less than approximately 0.1 nanometers), the first conformal non-polar layer 2202 will not provide for a sufficient energy barrier that enables a non-zero net charge along an interface with a subsequently formed ferroelectric layer. Without the non-zero net charge at the interface, the memory structure may be unable to output different levels of read currents, and hence the memory structure may be unable to output stored data states. In some embodiments, the first conformal non-polar layer 2202 is as described with regard to the non-polar layer 116 of FIG. 5A.

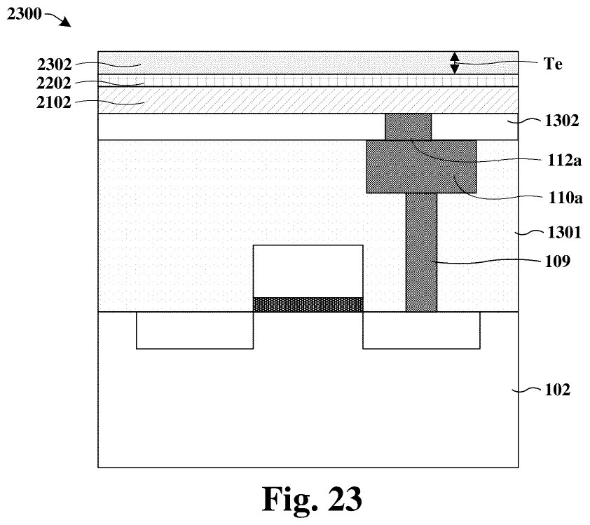

As illustrated by the cross-sectional view 2300 of FIG. 23, a first intermediate electrode layer 2302 is formed over the first conformal non-polar layer 2202. A process for forming the first intermediate electrode layer 2302 may be or comprise depositing the first intermediate electrode layer 2302 by DC sputtering, PVD, CVD, ALD, some other suitable deposition process, or any combination of the foregoing. In some embodiments, the first intermediate electrode layer 2302 is formed to have a thickness Te ranging from approximately 10 nanometers to approximately 100 nanometers, approximately 10 nanometers to approximately 50 nanometers, approximately 50 nanometers to approximately 100 nanometers, or some other suitable value. In some embodiments, the first intermediate electrode layer 2302 is as described with regard to the intermediate electrode 502 of FIG. 5A.

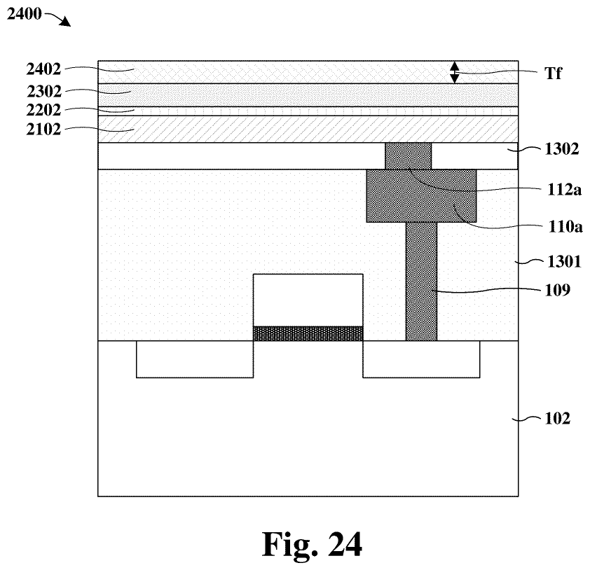

As illustrated by the cross-sectional view 2400 of FIG. 24, a conformal ferroelectric layer 2402 is formed over the first intermediate electrode layer 2302. A process for forming the conformal ferroelectric layer 2402 may be or comprise depositing the conformal ferroelectric layer 2402 by PVD, CVD, ALD, some other suitable deposition process, or any combination of the foregoing. In some embodiments, the conformal ferroelectric layer 2402 is formed to have a thickness TI ranging from approximately 0.1 nanometers to approximately 4 nanometers, from approximately 0.1 nanometers to approximately 2 nanometers, from approximately 2 nanometers to approximately 4 nanometers, or some other suitable value. In some embodiments, if the thickness T1 is too large (e.g., more than approximately 4 nanometers), the read current may be unable to sufficiently pass through the memory structure, negatively affecting the effectiveness of read operations. In some embodiments, if the thickness T1 is too small (e.g., less than approximately 0.1 nanometers), a subsequently formed ferroelectric layer may provide an insufficient amount of remanent polarization to store data reliably. In some embodiments, the conformal ferroelectric layer 2402 is as described with regard to the ferroelectric layer 504 of FIG. 5A.

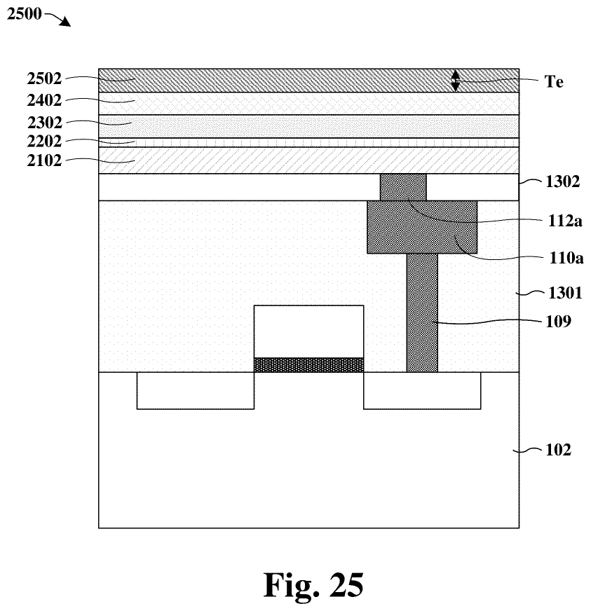

As illustrated by the cross-sectional view 2500 of FIG. 25, a second electrode layer 2502 is formed over the conformal ferroelectric layer 2402. In some embodiments, the second electrode layer 2502 is formed to have a thickness Te ranging from approximately 10 nanometers to approximately 100 nanometers, approximately 10 nanometers to approximately 50 nanometers, approximately 50 nanometers to approximately 100 nanometers, or some other suitable value. A process for forming the second electrode layer 2502 may be or comprise depositing the second electrode layer 2502 by DC sputtering, PVD, CVD, ALD, some other suitable deposition process, or any combination of the foregoing. In some embodiments, the second electrode layer 2502 is as described with regard to the top electrode 120 of FIG. 5A.

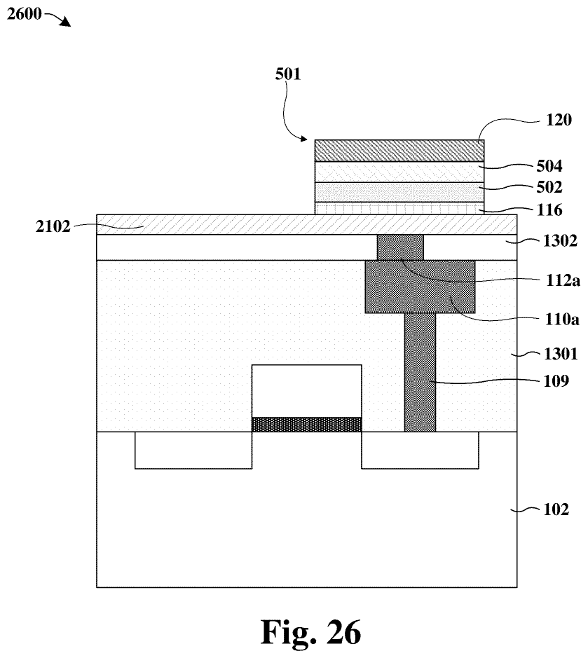

As illustrated by the cross-sectional view 2600 of FIG. 26, the first conformal non-polar layer 2202, the first intermediate electrode layer 2302, the conformal ferroelectric layer 2402, and the second electrode layer 2502 are patterned to respectively form a non-polar layer 116, an intermediate electrode 502, a ferroelectric layer 504, and a top electrode 120. The patterning may, for example, be performed by a photolithography/etching process and/or by some other suitable process. In some embodiments, the patterning comprises: forming a hard mask (not shown) over the second electrode layer 2502 using a photolithography/etching process and subsequently etching the first conformal non-polar layer 2202, the first intermediate electrode layer 2302, the conformal ferroelectric layer 2402, and the second electrode layer 2502 with the hard mask in place.

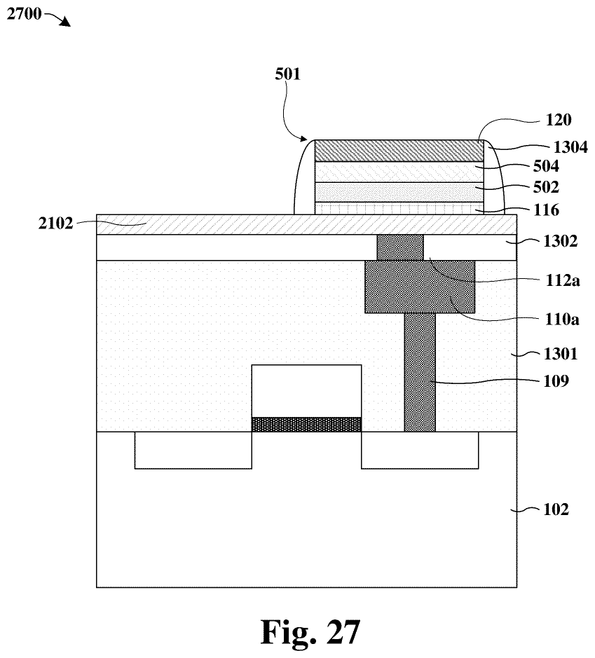

As illustrated by the cross-sectional view 2700 of FIG. 27, sidewall spacers 1304 are formed over the first electrode layer 2102 and along sidewalls of the non-polar layer 116, the intermediate electrode 502, the ferroelectric layer 504, and the top electrode 120. A process for forming the sidewall spacers 1304 may be or comprise depositing the sidewall spacers 1304 by PVD, CVD, ALD, some other suitable deposition process, or any combination of the foregoing.

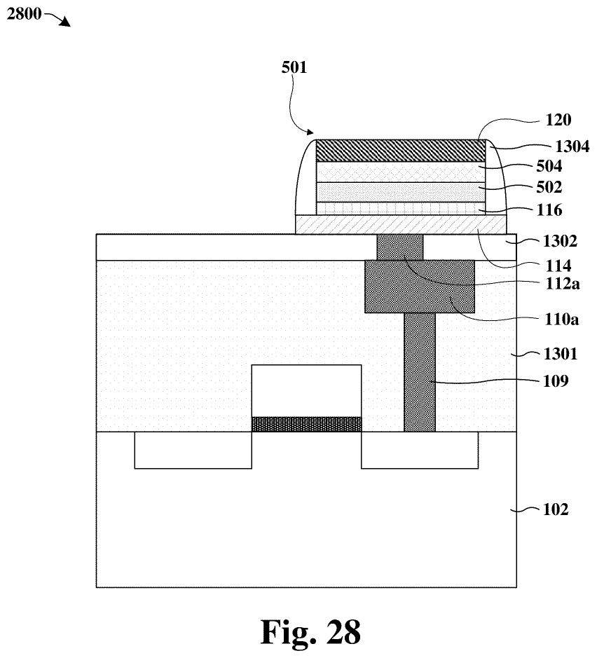

As illustrated by the cross-sectional view 2800 of FIG. 28, the first electrode layer 2102 is patterned to form a bottom electrode 114. The bottom electrode 114, the non-polar layer 116, the intermediate electrode 502, the ferroelectric layer 504, and the top electrode 120 define a memory structure 501. The patterning may, for example, be performed by a photolithography/etching process and/or by some other suitable process. In some embodiments, the patterning comprises: forming a hard mask (not shown) over the top electrode 120 and the sidewall spacers 1304 using a photolithography/etching process and subsequently etching the first electrode layer 2102 with the hard mask in place. In some embodiments, the top electrode and the sidewall spacers 1304 may serve as the hard mask.

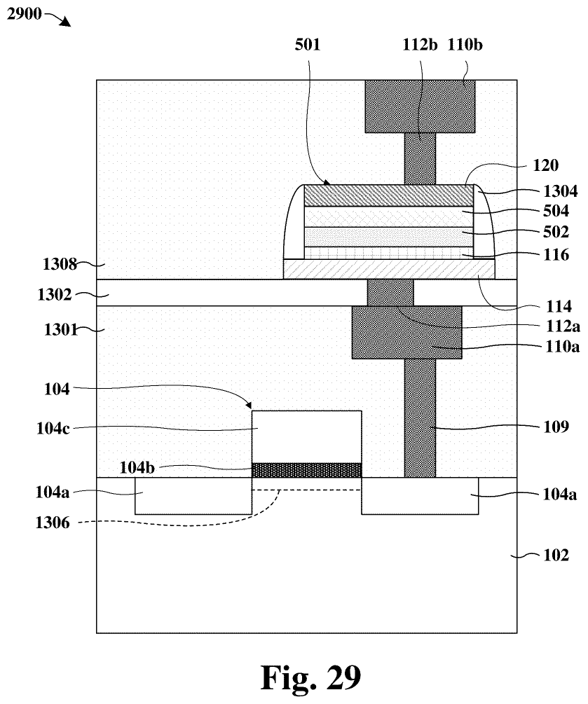

As illustrated by the cross-sectional view 2900 of FIG. 29, an upper dielectric structure 1308 is formed over the etch stop layer 1302. A second interconnect via 112b is formed over the memory structure 501 contacting the top electrode 120. Further, a second interconnect wire 110b is formed over and contacting the second interconnect via 112b.

In some embodiments, a BEOL process is subsequently performed over the top electrode 120. In alternative embodiments in which the memory structure 501 is as described with respect to FIG. 8, FIG. 9B, FIG. 9C, or FIG. 9E, the methods described with regard to FIGS. 22-23 may be omitted, and alternatively, a thermal process may be performed on the bottom electrode 114, the ferroelectric layer 504, and the top electrode 120 during the BEOL process to form a non-polar layer 116 between the bottom electrode 114 and the ferroelectric layer 504. In alternative embodiments in which the memory structure 501 is as described with respect to FIG. 8, FIG. 9A, FIG. 9C, or FIG. 9D, the methods described with regard to FIGS. 22-23 may be omitted, and alternatively, a thermal process may be performed on the bottom electrode 114, the ferroelectric layer 504, and the top electrode 120 during the BEOL process to form a second non-polar layer (not shown) between the top electrode 120 and the ferroelectric layer 504.

In alternative embodiments in which the memory structure 501 is as described with respect to FIG. 7A, the methods described with regard to FIG. 23 may be repeated after the methods described with regard to FIG. 24, such that a second intermediate electrode layer (not shown) is formed over the conformal ferroelectric layer 2402, and subsequently, the methods described with regard to FIG. 22 may be repeated to form a second conformal non-polar layer (not shown) over the second intermediate electrode layer. In alternative embodiments in which the memory structure 501 is as described with respect to FIG. 7B, the methods described with regard to FIG. 22 and FIG. 23 may be omitted and instead performed after the methods described with regard to FIG. 24, such that a second intermediate electrode layer (not shown) is formed over the conformal ferroelectric layer 2402, and subsequently, a second conformal non-polar layer (not shown) is formed over the second intermediate electrode layer.

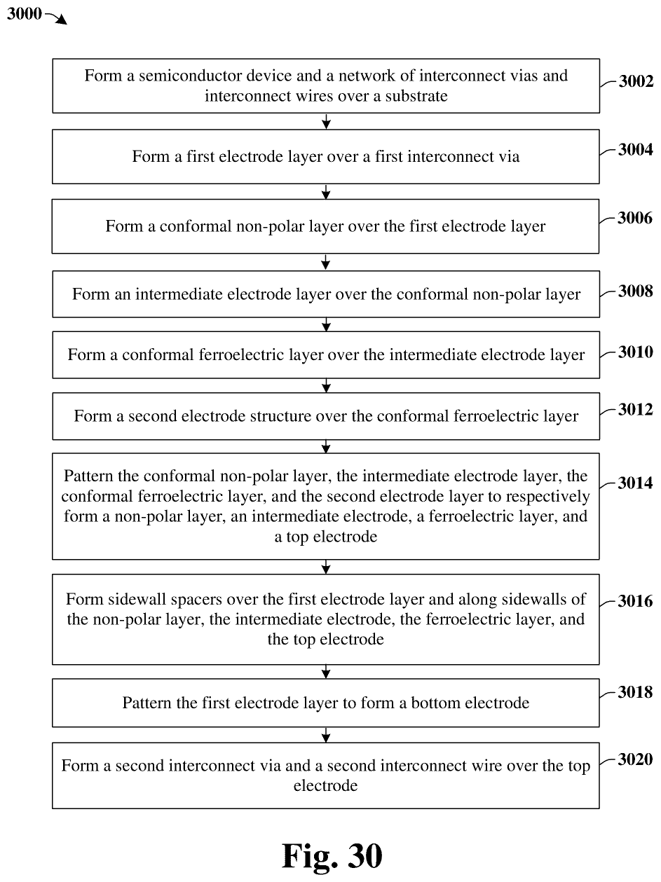

FIG. 30 illustrates a flowchart 3000 of some embodiments of the method of FIGS. 21-29. While the disclosed flowchart 3000 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 3002, a semiconductor device is formed and a network of interconnect vias and interconnect wires is formed over a substrate. See, for example, FIG. 21.

At act 3004, a first electrode layer is formed over a first interconnect via of the network of interconnect vias. See, for example, FIG. 21.

At act 3006, a conformal non-polar layer is formed over the first electrode layer. See, for example, FIG. 22.

At act 3008, an intermediate electrode layer is formed over the conformal non-polar layer. See, for example, FIG. 23.

At act 3010, a conformal ferroelectric layer is formed over the intermediate electrode layer. See, for example, FIG. 24.

At act 3012, a second electrode layer is formed over the conformal ferroelectric layer. See, for example, FIG. 25.

At act 3014, the conformal non-polar layer, the intermediate electrode structure, the conformal ferroelectric layer, and the second electrode layer are patterned to respectively form a non-polar layer, an intermediate electrode, a ferroelectric layer, and a top electrode. See, for example, FIG. 26.

At act 3016, sidewall spacers are formed over the first electrode layer and along sidewalls of the non-polar layer, the intermediate electrode, the ferroelectric layer, and the top electrode. See, for example, FIG. 27.

At act 3018, the first electrode layer is patterned to form a bottom electrode. See, for example, FIG. 28.

At act 3020, a second interconnect via and a second interconnect wire are formed over the top electrode. See, for example, FIG. 29.

Accordingly, in some embodiments, the present disclosure relates to an integrated chip, comprising: one or more interconnect wires and vias arranged within one or more interconnect dielectric layers over a substrate; a bottom electrode disposed over the one or more interconnect wires and vias and comprising a first material having a first work function; a top electrode disposed over the bottom electrode and comprising a second material having a second work function, wherein the first material is different than the second material, and wherein the first work function is different than the second work function; and an anti-ferroelectric layer disposed between the top and bottom electrodes.

In other embodiments, the present disclosure relates to an integrated chip, including a substrate and a memory structure disposed over the substrate and including a bottom electrode disposed over the substrate, a first non-polar layer disposed over the bottom electrode, a ferroelectric layer arranged over the first non-polar layer, and a top electrode disposed over the ferroelectric layer.

In other embodiments, the present disclosure relates to an integrated chip comprising: one or more interconnect wires and vias arranged within one or more interconnect dielectric layers over a substrate; an anti-ferroelectric tunnel junction (ATJ) structure arranged over and coupled to the one or more interconnect wires and vias, wherein the ATJ structure comprises: a first electrode comprising a first material having a first work function; a second electrode comprising a second material having a second work function that is different than the first work function; an anti-ferroelectric layer disposed between the first and second electrodes; and a non-polar layer arranged between the first electrode and the anti-ferroelectric layer.

In other embodiments, the present disclosure relates to a method including forming a bottom electrode structure over a substrate, forming a first non-polar structure over the bottom electrode structure, forming a first intermediate electrode structure over the first non-polar structure, forming a ferroelectric structure over the first intermediate electrode structure, and forming a top electrode structure over the ferroelectric structure.

In other embodiments, the present disclosure relates to a method for forming an integrated chip, including forming a bottom electrode structure over a substrate, forming a ferroelectric structure over the bottom electrode structure, forming a top electrode structure over the ferroelectric structure, patterning the ferroelectric structure and the top electrode structure to respectively form a ferroelectric layer and a top electrode, patterning the bottom electrode structure to form a bottom electrode, and performing a thermal process on the bottom electrode, the ferroelectric layer, and the top electrode to form a first non-polar layer between the bottom electrode and the ferroelectric layer.

In yet other embodiments, the present disclosure relates to a method comprising: forming an interconnect structure over a substrate; forming a bottom electrode over a substrate and comprising a first material having a first work function; forming an anti-ferroelectric layer over the bottom electrode; forming a top electrode over the anti-ferroelectric layer and comprising a second material having a second work function different than the first work function; and forming a non-polar layer between the anti-ferroelectric layer and the bottom electrode or between the anti-ferroelectric layer and the top electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1-17. (canceled)

18. A method comprising:
forming an interconnect structure over a substrate;
forming a bottom electrode over the substrate and comprising a first material having a first work function;
forming an anti-ferroelectric layer over the bottom electrode;
forming a top electrode over the anti-ferroelectric layer and comprising a second material having a second work function different than the first work function; and
forming a non-polar layer between the anti-ferroelectric layer and the bottom electrode or between the anti-ferroelectric layer and the top electrode.

19. The method of claim 18, wherein the anti-ferroelectric layer is crystalline and is crystallized at a temperature less than or equal to 400 degrees Celsius.

20. The method of claim 18, wherein the interconnect structure is formed at a maximum temperature value, and wherein the anti-ferroelectric layer has a crystallization temperature that is less than or equal to the maximum temperature value.

21. The method of claim 18, wherein the anti-ferroelectric layer has a thickness of between approximately 0.5 nanometers and approximately 5 nanometers.

22. The method of claim 18, wherein a difference between the first work function and the second work function is greater than or equal to approximately 0.3 eV.

23. A method, comprising:
depositing a bottom electrode layer over a substrate;
depositing a non-polar material over the bottom electrode layer;
depositing a ferroelectric material over the bottom electrode layer;
forming a top electrode layer over the non-polar material and the ferroelectric material; and
performing one or more etching processes to remove peripheral portions of the top electrode layer, the ferroelectric material, the non-polar material, and the bottom electrode layer.

24. The method of claim 23, wherein the bottom electrode layer comprises a first material having a first work function and the top electrode layer comprises a second material having a second work function that is different than the first work function.

25. The method of claim 23, further comprising:
depositing a second non-polar material over the ferroelectric material, wherein the top electrode layer is formed over the second non-polar material; and
wherein the one or more etching processes remove peripheral portions of the second non-polar material.

26. The method of claim 23, further comprising:
depositing an intermediate electrode layer over the bottom electrode layer, wherein the intermediate electrode layer vertically separates the non-polar material and the ferroelectric material; and
wherein the one or more etching processes remove peripheral portions of the intermediate electrode layer.

27. The method of claim 26, further comprising:
depositing a second intermediate electrode layer and a second non-polar material over the ferroelectric material; and
wherein the one or more etching processes remove peripheral portions of the second intermediate electrode layer and the second non-polar material.

28. The method of claim 23, wherein the ferroelectric material has a stepped profile in a cross-sectional view.

29. A method, comprising:
depositing a bottom electrode layer over a substrate;
depositing a non-polar dielectric layer over the bottom electrode layer, wherein the non-polar dielectric layer comprises a dielectric constant of greater than approximately 8; and
depositing a top electrode layer over the non-polar dielectric layer, wherein the top electrode layer is a different material than the bottom electrode layer.

30. The method of claim 29, further comprising:
depositing an anti-ferroelectric layer over the bottom electrode layer, wherein the top electrode layer is deposited over the anti-ferroelectric layer.

31. The method of claim 29, wherein the non-polar dielectric layer is deposited to a thickness of less than or equal to approximately 2 nanometers.

32. The method of claim 29, further comprising:
depositing a ferroelectric material over the bottom electrode layer, wherein the top electrode layer is formed over the ferroelectric material.

33. The method of claim 32, wherein the ferroelectric material has a thickness that varies over a width of the ferroelectric material in a cross-sectional view, the thickness having a maximum value at non-zero distances from opposing outermost sidewalls of the ferroelectric material.

34. The method of claim 32, wherein the ferroelectric material comprises an oxygen concentration that increases from a center of the ferroelectric material to a topmost surface of the ferroelectric material.

35. The method of claim 32, wherein the top electrode layer comprises a refractory nitride material having a lower concentration of nitrogen near the ferroelectric material than an upper region of the top electrode layer.

36. The method of claim 32, wherein the bottom electrode layer comprises a refractory nitride material having a lower concentration of nitrogen near the ferroelectric material than a lower region of the bottom electrode layer.

37. The method of claim 32, further comprising:
depositing a second non-polar dielectric layer over the ferroelectric material, wherein the top electrode layer is formed over the second non-polar dielectric layer.
